(19) United States
(12) Patent Application Publication
(10) Pub. No.: US 2021/0320270 A1
(43) Pub. Date: Oct. 14, 2021

(54) NEAR-INFRARED TERNARY TANDEM SOLAR CELLS

(71) Applicant: The Regents of the University of Michigan, Ann Arbor, MI (US)

(72) Inventors: Yongxi Li, Ann Arbor, MI (US); Stephen R. Forrest, Ann Arbor, MI (US)

(21) Appl. No.: 17/036,472

(22) Filed: Sep. 29, 2020

Related U.S. Application Data
(60) Provisional application No. 62/908,172, filed on Sep. 30, 2019.

(51) Int. Cl. H01L 51/44; H01L 51/00; C09D 1/00; C09D 5/00

(52) U.S. Cl. CPC H01L 51/441; H01L 51/0046; C09D 5/006; C09D 1/00; H01L 51/0067

(57) ABSTRACT

A photovoltaic cell comprises an anode, a cathode, a first subcell positioned between the anode and the cathode, the first subcell comprising a first donor material and a first acceptor material, and a second subcell positioned between the first subcell and the cathode, the second subcell comprising a second donor material and a second acceptor material. A method of fabricating a photovoltaic cell is also described.

### CROSS-REFERENCE TO RELATED APPLICATIONS

This application claims priority to U.S. Provisional Patent Application No. 62/908,172, filed on Sep. 30, 2019, incorporated herein by reference in its entirety.

### STATEMENT REGARDING FEDERALLY SPONSORED RESEARCH OR DEVELOPMENT

This invention was made with government support under grant no. DE-EE00006708 awarded by the Department of Energy and grant no. N00014-17-1-2211 awarded by the Department of the Navy, Office of Naval Research. The government has certain rights in the invention.

### BACKGROUND OF THE INVENTION

Organic photovoltaics (OPVs), have the potential for producing low-cost and ubiquitous renewable energy in the future, due to their reliance on abundant and environmentally friendly carbon-based materials. Furthermore, their ability to be deposited on flexible, light weight and transparent substrates provides a path to mass production via continuous roll-to-roll deposition. By stacking both large and small energy-gap cells into a tandem OPV, the efficiency can be improved by minimizing the thermalization losses. However, the relative lack of high performance, small-energy gap cells has impeded the progress in tandem solar cell efficiency. Recently, an organic tandem solar cell was demonstrated with a power conversion efficiency as high as PCE=15.0% under 1 sun, AM 1.5G spectral illumination (X. Z. Che et al., Nature Energy 2018, 3, 422-427, incorporated herein by reference). This result was based on the combination of a fullerene based cell deposited via vacuum thermal evaporation (VTE), along with a solution-processed, two-component NIR non-fullerene acceptor (NFA) subcell absorbing between wavelengths of 650-850 nm with PCE˜11%.

Although recent rapid developments of small energy gap NFAs provides opportunities to achieve high efficiency NIR cells, only a few non-fullerene acceptors have significant absorption and wavelengths greater than 1000 nm. The successful design of narrow energy gap NFAs requires precise tuning of the energy levels while maintaining a sufficient heterojunction energy offset to efficiently drive the dissociation of excitons. In this context, ternary blend OPVs containing one additional electron donor or acceptor material are a promising way to overcome the efficiency bottleneck encountered by conventional binary cells.

Thus, there is a need in the art for a new efficient NIR OPV that reduces energy losses. The present invention satisfies this need.

### SUMMARY OF THE INVENTION

In one aspect, a photovoltaic cell comprises an anode, a cathode, a first subcell positioned between the anode and the cathode, the first subcell comprising a first donor material and a first acceptor material, and a second subcell positioned between the first subcell and the cathode, the second subcell comprising a second donor material and a second acceptor material. In one embodiment, the second subcell further comprises a third acceptor material. In one embodiment, the first subcell further comprises a third donor material. In one embodiment, the first subcell further comprises a fourth acceptor material. In one embodiment, the first subcell further comprises a third acceptor material and the second subcell further comprises a third donor material.

In one embodiment, the second and third acceptor materials are NIR non-fullerene acceptor materials. In one embodiment, the second, third, and fourth acceptor materials are NIR non-fullerene acceptor materials. In one embodiment, the second acceptor material is selected from the group consisting of TT-FIC, BT-CIC, and BT-IC. In one embodiment, the second donor material is PCE-10. In one embodiment, the cell further comprises a recombination zone comprising at least one layer, positioned between the first subcell and the second subcell. In one embodiment, the recombination zone comprises a material selected from the group consisting of PEDOT:PSS, Ag, BPhen, and Fullerene. In one embodiment, the Fullerene is Fullerene C₆₀.

In one embodiment, the cell further comprises an anti-reflective coating. In one embodiment, the anti-reflective coating comprises a material selected from the group consisting of MgF₂ and SiO₂. In one embodiment, the cell further comprises a protective layer in front of the anode. In one embodiment, the cell further comprises an anti-reflective layer positioned between the protective layer and the anode. In one embodiment, the cell further comprises an anti-reflective layer positioned in front of the protective layer. In one embodiment, the protective layer comprises glass. In one embodiment, the cell further comprises an electron transport layer positioned between the second subcell and the cathode. In one embodiment, the electron transport layer comprises TmPyPB.

In another aspect, a method of fabricating a photovoltaic cell comprises positioning a substrate in a first chamber, establishing a vacuum in the first chamber, depositing a first subcell comprising at least one material over the substrate, depositing a recombination zone over the first subcell, moving the substrate, first subcell, and recombination zone to a second chamber comprising ultrapure N₂ gas, and depositing a second subcell over the recombination zone in the second chamber. In one embodiment, the method further comprises spin-coating a layer of polymer over the recombination zone.

In one embodiment, the method further comprises depositing an anti-reflective coating on the substrate. In one embodiment, the anti-reflective coating is deposited by VTE or electron beam deposition. In one embodiment, the method further comprises patterning an anode on the substrate prior to depositing the first subcell. In one embodiment, the anode comprises ITO. In one embodiment, the method further comprises moving the photovoltaic cell back to the first chamber after depositing the second subcell and establishing a vacuum in the first chamber. In one embodiment, the method further comprises depositing a cathode over the second subcell. In one embodiment, the method further comprises depositing an electron transport layer over the second subcell.

In one embodiment, the method further comprises the steps of forming a second subcell material, comprising the steps of dissolving at least one material in chlorobenzene:chloroform to form a mixture, stirring the mixture, and heating the mixture to form the second subcell material, and spin-coating the second subcell material over the recombination zone to form the second subcell. In one embodiment, the at least one material is selected from the group consisting of PCE-10, BT-CIC, TT-FIC, and a compound of formula (I)-(III)

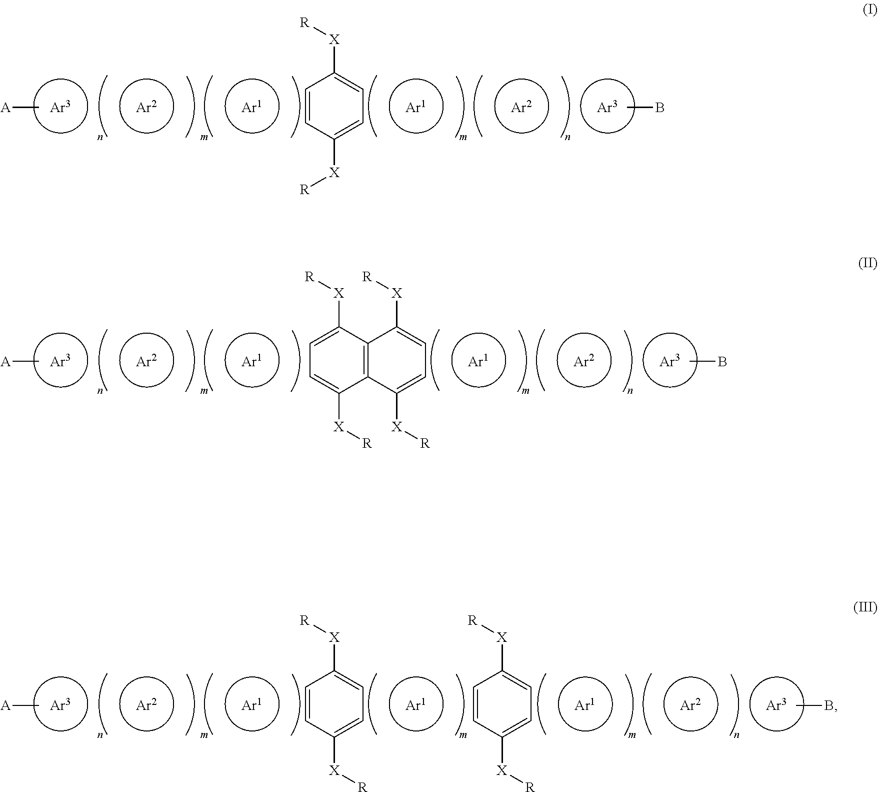

wherein Ar¹, Ar² and Ar³ each individually represent aromatic groups, each m is independently an integer from 0 to 10, each n is independently an integer from 0 to 10, each X is independently selected from the group consisting of oxygen, carbon, hydrogen, sulfur, selenium and nitrogen, each R is individually linear or branched saturated or unsaturated non-aromatic hydrocarbon in the C₁-C₂₀ range, and A and B are each independently selected from the group consisting of:

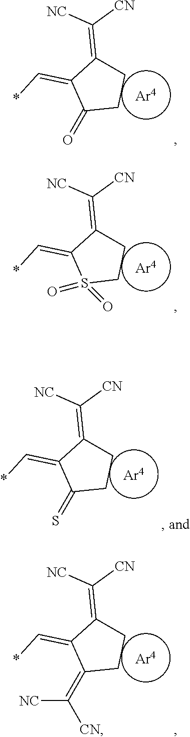

wherein Ar⁴ is an aromatic group which is fused to the adjacent ring. In one embodiment, the at least one material consists of PCE-10, BT-CIC, TT-FIC, and a compound of formula (I)-(III)

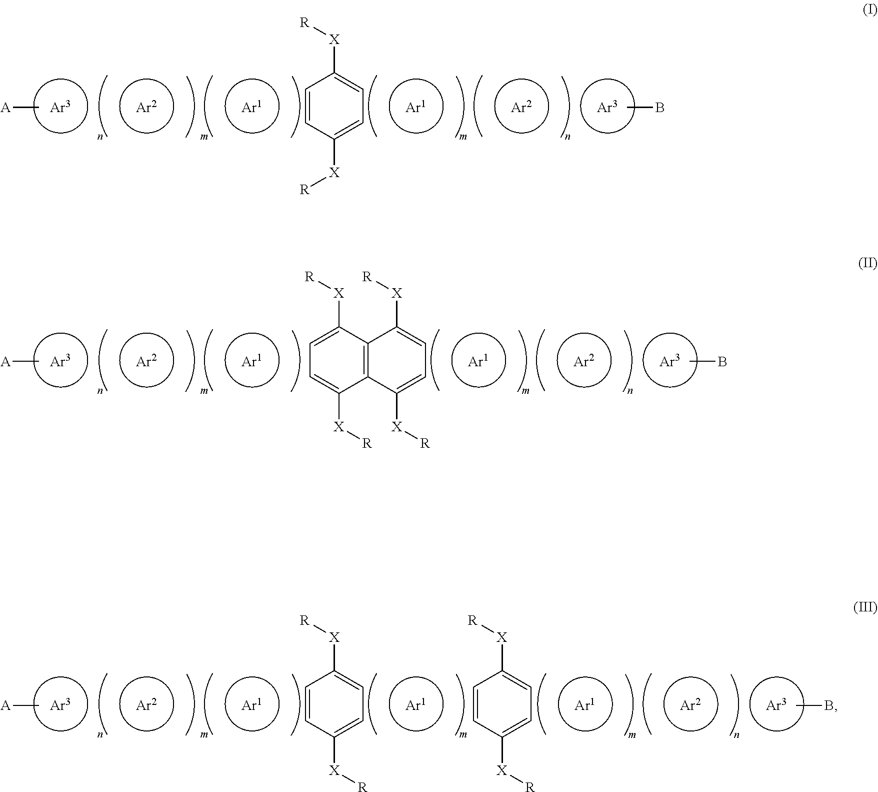

wherein Ar¹, Ar² and Ar³ each individually represent aromatic groups, each m is independently an integer from 0 to 10, each n is independently an integer from 0 to 10, each X is independently selected from the group consisting of oxygen, carbon, hydrogen, sulfur, selenium and nitrogen, each R is individually linear or branched saturated or unsaturated non-aromatic hydrocarbon in the C₁-C₂₀ range, and A and B are each independently selected from the group consisting of:

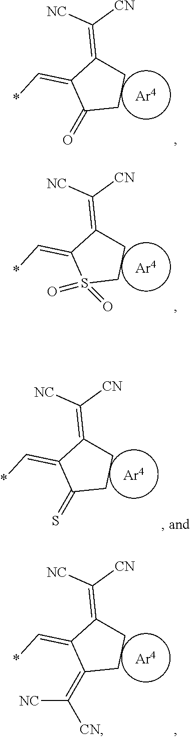

wherein Ar⁴ is an aromatic group which is fused to the adjacent ring.

### BRIEF DESCRIPTION OF THE DRAWINGS

The foregoing purposes and features, as well as other purposes and features, will become apparent with reference to the description and accompanying figures below, which are included to provide an understanding of the invention and constitute a part of the specification, in which like numerals represent like elements, and in which:

FIG. 1A shows a diagram of layers of a single-junction solar cell or OPV;

FIG. 1B shows a diagram of layers of a multi junction solar cell or OPV;

FIG. 2A shows molecular structural formulae of PCE-10, BT-CIC and TT-FIC used in the single junction and tandem cells;

FIG. 2B shows the UV-Vis absorption spectra of PCE-10, BT-CIC and TT-FIC thin films;

FIG. 2C shows a synthetic route for TT-FIC;

FIG. 2D is a ¹H NMR of TT-FIC in CDCl₃;

FIG. 2E is a ¹³C NMR of TT-FIC in CDCl₃;

FIG. 3A is a graph of UV-Vis absorption spectra of ternary blend films;

FIG. 3B is an energy level diagram of PCE-10, BT-CIC and TT-FIC relative to vacuum obtained from cyclic voltammetry. Numbers are in eV relative to the vacuum level;

FIG. 4 is a graph of cyclic voltammetry data of BT-CIC and TT-FIC in CH₃CN/0.1 M [nBu₄N]⁺[PF₆]⁻ at 100 mV s⁻¹, the horizontal voltage scale refers to the Ag/AgCl electrode;

FIG. 5A shows 2D glancing incidence x-ray diffraction (GIXD) patterns of binary and ternary blends;

FIG. 5B is a graph of in-plane (dotted line) and out-of-plane (solid line) x-ray scattering patterns;

FIG. 5C is a graph of resonant soft x-ray diffraction of binary and ternary blends. Q is the scattering vector;

FIG. 6 is a set of AFM topographic images (3×3 μm) of various compounds;

FIG. 7A is a graph of Current-density-voltage characteristics of ternary cells based on PCE-10, BT-CIC and TT-FIC;

FIG. 7B is a graph of V_{OC}, J_{SC}, FF and PCE of optimized ternary cells as functions of TT-FIC:BT-CIC blend ratios, under 1 sun intensity (100 mW/cm²), AM 1.5G simulated illumination;

FIG. 7C is an efficiency histogram for a population of 50 optimized ternary cells;

FIG. 7D is a graph of external quantum efficiency (EQE) spectra of ternary cells with various blending ratios;

FIG. 8A is a schematic of a tandem device showing layer thicknesses and compositions;

FIG. 8B is the optical field intensity distribution within the cell obtained via the transfer matrix method;

FIG. 8C is a graph of current-density-voltage characteristics of the optimized tandem cell together with the single junction subcells;

FIG. 8D is a graph of current density-voltage characteristics of tandem cells with various DTDCPB:C₇₀ thicknesses;

FIG. 8E is an efficiency histogram for a population of 32 optimized tandem cells;

FIG. 8F is a graph of measured reflection ratio between the glass substrates with and without ARC;

FIG. 8G is a graph of J_{SC}, V_{oc}, and FF as a function of incident light power density;

FIG. 8H is a graph of external quantum efficiency (EQE) spectra of the tandem and discrete subcells;

FIG. 9 is a graph of fill factor vs. light intensity for PCE-10:BT-CIC:TT-FIC (1:1.25:0.5, w/w/w) single junction cells;

FIG. 10A is a graph of measured ternary device parameters over time; and

FIG. 10B is a graph of measured tandem device parameters over time.

### DETAILED DESCRIPTION

It is to be understood that the figures and descriptions of the present invention have been simplified to illustrate elements that are relevant for a clear understanding of the present invention, while eliminating, for the purpose of clarity, many other elements found in related systems and methods. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, exemplary methods and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, ±10%, ±5%, ±1%, and ±0.1% from the specified value, as such variations are appropriate.

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, 6 and any whole and partial increments therebetween. This applies regardless of the breadth of the range.

As used herein, the terms “electrode” and “contact” may refer to a layer that provides a medium for delivering photo-generated current to an external circuit or providing a bias current or voltage to the device. That is, an electrode, or contact, provides the interface between the active regions of an organic photosensitive optoelectronic device and a wire, lead, trace or other means for transporting the charge carriers to or from the external circuit. Examples of electrodes include anodes and cathodes, which may be used in a photosensitive optoelectronic device.

As used herein, the term “transparent” may refer to an electrode that permits at least 50% of the incident electromagnetic radiation in relevant wavelengths to be transmitted through it. In a photosensitive optoelectronic device, it may be desirable to allow the maximum amount of ambient electromagnetic radiation from the device exterior to be admitted to the photoconductive active interior region. That is, the electromagnetic radiation must reach a photoconductive layer(s), where it can be converted to electricity by photoconductive absorption. This often dictates that at least one of the electrical contacts should be minimally absorbing and minimally reflecting of the incident electromagnetic radiation. In some cases, such a contact should be transparent or at least semi-transparent.

As used herein, the term “semi-transparent” may refer to an electrode that permits some, but less than 50% transmission of ambient electromagnetic radiation in relevant wavelengths. The opposing electrode may be a reflective material so that light which has passed through the cell without being absorbed is reflected back through the cell.

As used and depicted herein, a “layer” refers to a member or component of a photosensitive device whose primary dimension is X-Y, i.e., along its length and width. It should be understood that the term layer is not necessarily limited to single layers or sheets of materials. In addition, it should be understood that the surfaces of certain layers, including the interface(s) of such layers with other material(s) or layers(s), may be imperfect, wherein said surfaces represent an interpenetrating, entangled or convoluted network with other material(s) or layer(s). Similarly, it should also be understood that a layer may be discontinuous, such that the continuity of said layer along the X-Y dimension may be disturbed or otherwise interrupted by other layer(s) or material(s).

As used herein, a “photoactive region” refers to a region of the device that absorbs electromagnetic radiation to generate excitons. Similarly, a layer is “photoactive” if it absorbs electromagnetic radiation to generate excitons. The excitons may dissociate into an electron and a hole in order to generate an electrical current.

As used herein, the terms “donor” and “acceptor” refer to the relative positions of the highest occupied molecular orbital (“HOMO”) and lowest unoccupied molecular orbital (“LUMO”) energy levels of two contacting but different organic materials. It is energetically favorable, in the absence of an external bias, for electrons at a donor-acceptor junction to move into the acceptor material, and for holes to move into the donor material.

As used herein, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Because ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, the term “band gap” (Eg) of a polymer may refer to the energy difference between the HOMO and the LUMO. The band gap is typically reported in electronvolts (eV). The band gap may be measured from the UV-vis spectroscopy or cyclic voltammetry. A “low band gap” polymer may refer to a polymer with a band gap below 2 eV, e.g., the polymer absorbs light with wavelengths longer than 620 nm.

As used herein, the term “excitation binding energy” (E_{B}) may refer to the following formula: E_{B}=(M⁺+M⁻)−(M*+M), where M⁺ and M⁻ are the total energy of a positively and negatively charged molecule, respectively; M* and M are the molecular energy at the first singlet state (S₁) and ground state, respectively. Excitation binding energy of acceptor or donor molecules affects the energy offset needed for efficient exciton dissociation. In certain examples, the escape yield of a hole increases as the HOMO offset increases. A decrease of exciton binding energy E_{B} for the acceptor molecule leads to an increase of hole escape yield for the same HOMO offset between donor and acceptor molecules.

As used herein, power conversion efficiency (η_{ρ}) may be expressed as:

$${η}_{ρ} = \frac{{V}_{OC} * F F * {J}_{SC}}{{P}_{O}}$$

wherein V_{OC} is the open circuit voltage, FF is the fill factor, J_{SC} is the short circuit current, and P_{O} is the input optical power.

### Organic Photovoltaic Cells

As disclosed herein, the various compositions or molecules within an active region or layer of a photovoltaic cell may be provided within a single-junction solar cell or a tandem or multi junction solar cell.

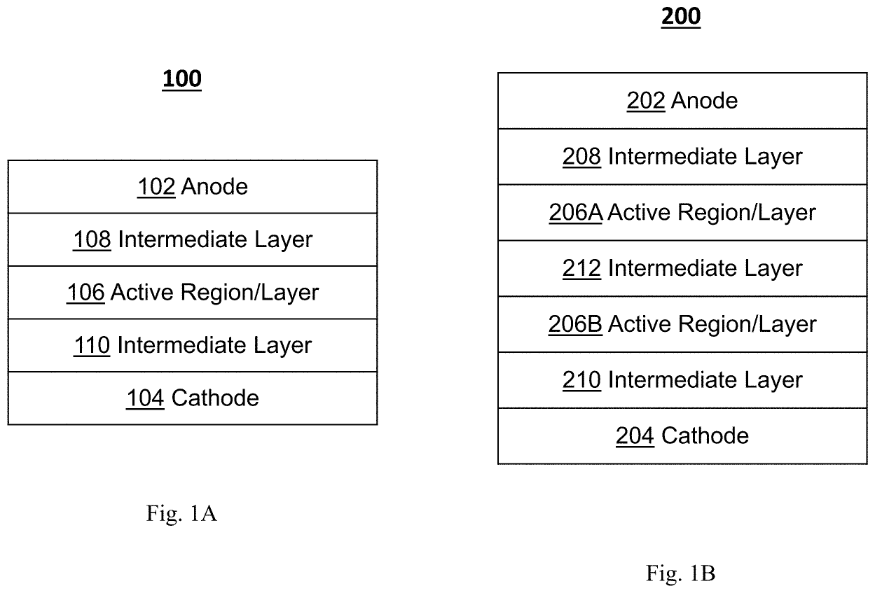

FIG. 1A depicts an example of various layers of a single junction solar cell or organic photovoltaic cell (OPV) 100 having a NIR non-fullerene acceptor composition. The OPV cell may include two electrodes having an anode 102 and a cathode 104 in superposed relation, at least one donor composition, and at least one acceptor composition, wherein the donor-acceptor material or active layer 106 is positioned between the two electrodes 102, 104. At least one intermediate layer 108 may be positioned between the anode 102 and the active layer 106. Additionally, or alternatively, at least one intermediate layer 110 may be positioned between the active layer 106 and cathode 104.

The anode 102 may include a conducting oxide, thin metal layer, or conducting polymer. In some examples, the anode 102 includes a (e.g., transparent) conductive metal oxide such as indium tin oxide (ITO), tin oxide (TO), gallium indium tin oxide (GITO), zinc oxide (ZO), or zinc indium tin oxide (ZITO). In other examples, the anode 102 includes a thin metal layer, wherein the metal is selected from the group consisting of Ag, Au, Pd, Pt, Ti, V, Zn, Sn, Al, Co, Ni, Cu, Cr, or combinations thereof. In yet other examples, the anode 102 includes a (e.g., transparent) conductive polymer such as polyanaline (PANI), or 3,4-polyethyl-enedioxythiophene:polystyrenesulfonate (PEDOT:PSS).

The thickness of the anode 102 may be 0.1-100 nm, 1-10 nm, 0.1-10 nm, or 10-100 nm.

The cathode 104 may be a conducting oxide, thin metal layer, or conducting polymer similar or different from the materials discussed above for the anode 102. In certain examples, the cathode 104 may include a metal or metal alloy. The cathode 104 may include Ca, Al, Mg, Ti, W, Ag, Au, or another appropriate metal, or an alloy thereof.

The thickness of the cathode 104 may be 0.1-100 nm, 1-10 nm, 0.1-10 nm, or 10-100 nm.

As noted above, the OPV may include one or more charge collecting/transporting intermediate layers positioned between an electrode 102, 104 and the active region or layer 106. The intermediate layer 108, 110 may be a metal oxide. In certain examples, the intermediate layer 108, 110 includes MoO₃, V₂O₅, ZnO, or TiO₂. In some examples, the first intermediate layer 108 has a similar composition as the second intermediate layer 110. In other examples, the first and second intermediate layers 108, 110 have different compositions.

The thickness of each intermediate layer may be 0.1-100 nm, 1-10 nm, 0.1-10 nm, or 10-100 nm.

The active region or layer 106 positioned between the electrodes 102, 104 includes a composition or molecule having an acceptor and a donor. The composition may be arranged as an acceptor-donor-acceptor (A-D-A).

FIG. 1B depicts an example of various layers of a tandem or multi junction solar cell or organic photovoltaic cell (OPV) 200 having a NIR non-fullerene acceptor composition. The OPV cell may include two electrodes having an anode 202 and a cathode 204 in superposed relation, at least one donor composition, and at least one acceptor composition positioned within a plurality of active layers or regions 206A, 206B between the two electrodes 202, 204. While only two active layers or regions 206A, 206B are depicted in FIG. 1B, additional active layers or regions are also possible.

At least one intermediate layer 208 may be positioned between the anode 202 and a first active layer 206A. Additionally, or alternatively, at least one intermediate layer 210 may be positioned between the second active layer 206B and cathode 204.

At least one intermediate layer 212 may be positioned between the first active layer 206A and the second active layer 206B.

The compositions, thicknesses, etc. of each layer may be the same as those discussed with reference to FIG. 1A.

The active region or layer 106, 206A, 206B positioned between the electrodes includes a composition or molecule having an acceptor and a donor. The composition may be arranged as an acceptor-donor-acceptor (A-D-A).

In one aspect of the invention, ternary blends of two NIR non-fullerene acceptors with a polymer donor are used to significantly reduce energy losses. A narrow energy gap non-fullerene acceptor, TT-FIC (4,4,10,10-tetrakis(4-hexylphenyl)-4,10-dihydrothieno [2″,3″:4′,5′]thieno[3′,2′:4,5] cyclopenta[1,2-b]thieno[2,3-d]thiophene-2,8-diyl)bis(2-(3-oxo-2,3-dihydroinden-5,6-difluoro-1-ylidene) malononitrile) sharing similar lowest unoccupied molecular orbital (LUMO) energies with a second acceptor BT-CIC, (absorption up to 1000 nm) is blended with the polymer PCE-10 (poly[4,8-bis(5-(2-ethylhexyl)thiophen-2-yl)benzo[1,2-b:4,5-bldithiophene-co-3-fluorothieno[3,4-b]thio-phene-2-carboxylate]). The resulting small differences in offset energies (40 meV) between the LUMOs of the acceptors and the highest occupied molecular orbitals (HOMOs) of the donors, along with the significantly different energy gaps (by 0.11 eV) of the acceptors, result in an open circuit voltage (V_{OC}) that is close to the maximum possible for this narrow energy gap system.

In one embodiment, the non-fullerene compound is a compound of formula (I), (II) or (III):

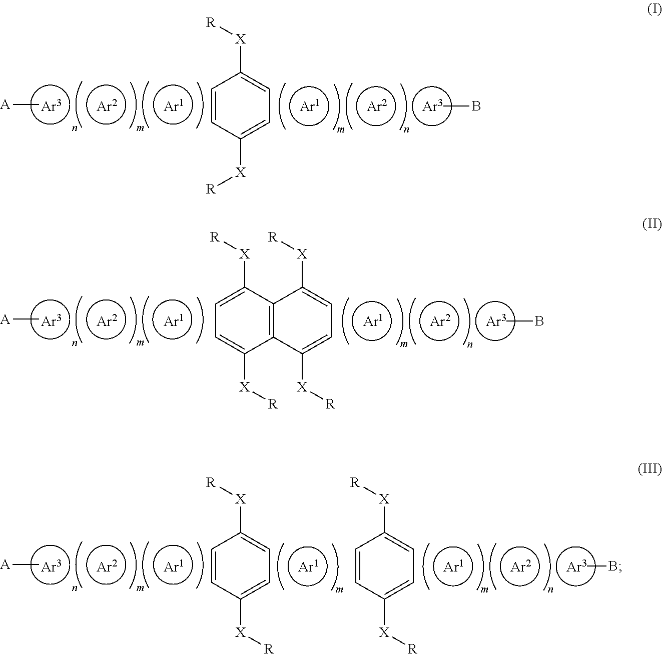

wherein Ar¹, Ar² and Ar³ each individually represent aromatic groups;
each m is independently an integer from 0 to 10;
each n is independently an integer from 0 to 10;
each X is independently selected from the group consisting of oxygen, carbon, hydrogen, sulfur, selenium and nitrogen;
each R is individually linear or branched saturated or unsaturated non-aromatic hydrocarbon in the C₁-C₂₀ range; and
A and B are each independently selected from the group consisting of:

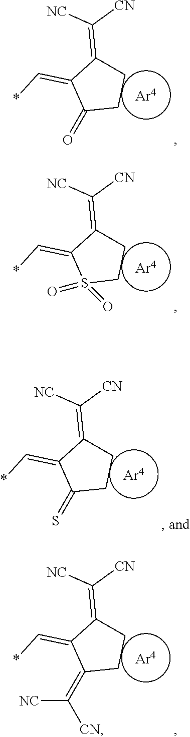

wherein Ar⁴ is an aromatic group which is fused to the adjacent ring.

In one embodiment, Ar¹, Ar², and Ar³ represent aromatic groups. The aromatic groups may be 5- or 6-membered cyclic rings. The cyclic rings may also be heterocyclic rings, wherein one carbon has been replaced by a non-carbon atom. In certain examples, the non-carbon atom within the heterocyclic ring may be nitrogen or a chalcogen such as oxygen, sulfur, selenium, or tellurium.

In one embodiment, Ar¹ may include an aromatic group which is conjugated fused connected to a benzene ring in the compound. In one embodiment, each Ar¹ may be individually selected from the group consisting of

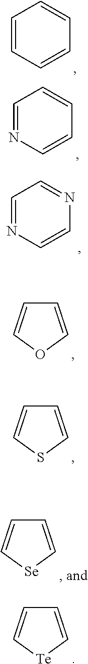

In one embodiment, Ar² may include an aromatic group which is conjugated fused connected to a Ar¹ ring in the compound. Each Ar² may be individually selected from the group consisting of:

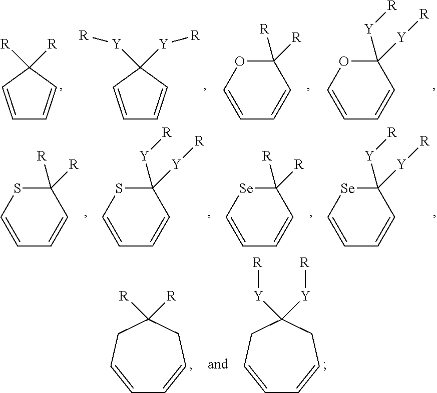

wherein each Y is an aryl group, an aromatic hydrocarbon, a five-membered cyclic ring attached to a R substituent (e.g., a hydrocarbon chain), wherein one carbon atom of the cyclic ring has been replaced by a chalcogen such as oxygen, sulfur, selenium, or tellurium; and each R is individually linear or branched saturated or unsaturated non-aromatic hydrocarbon in the C₁-C₂₀ range.

In one embodiment, each Y is independently selected from the group consisting of:

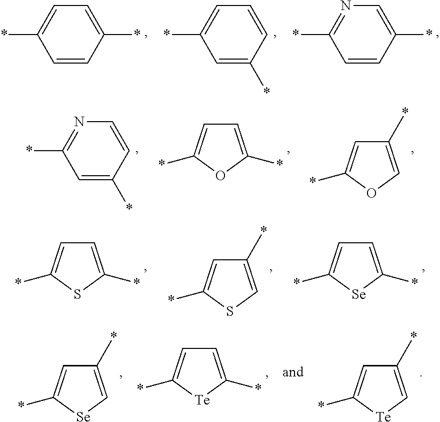

In on embodiment, R is selected from the group consisting of

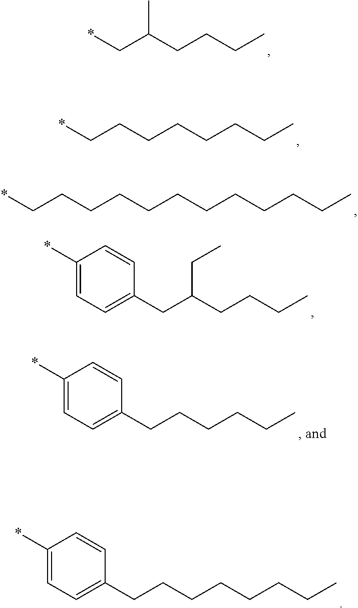

In one embodiment, Y—R is selected from the group consisting of

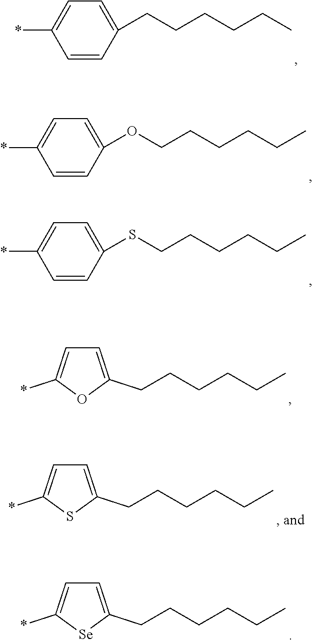

In one embodiment, Ar³ may include an aromatic group which is conjugated fused connected to a benzene ring in the compound. In one embodiment, each Ar³ may be individually selected from the group consisting of

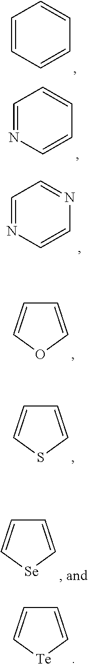

In one embodiment, Ar⁴ is an aromatic group selected from the group consisting of:

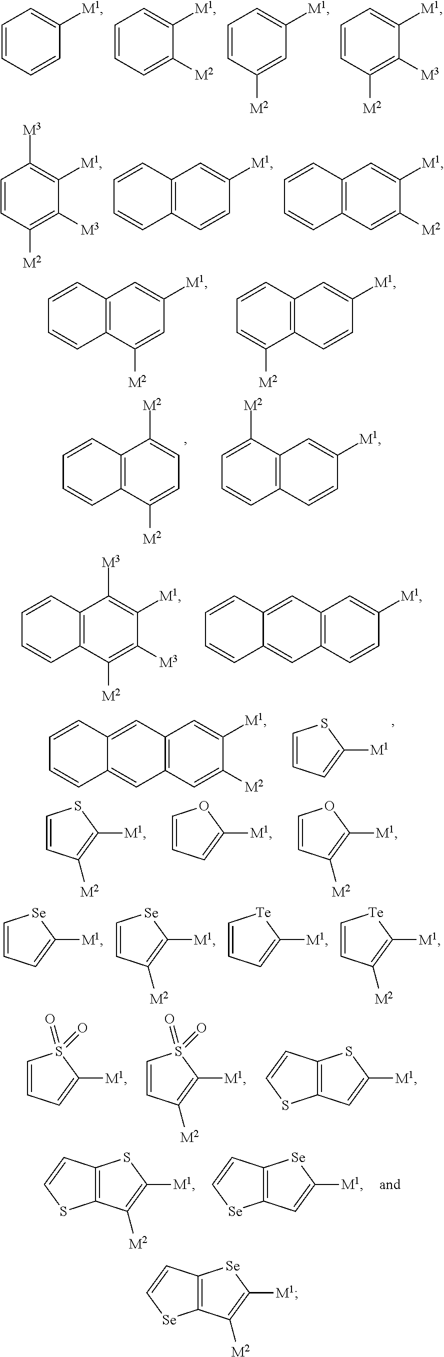

wherein M1-M4 are each individually selected from the group consisting of hydrogen, fluorine, chlorine, bromine, iodine, astatine, and cyano groups.

Specific examples of compounds of formula (I)-(III) may be found in PCT Application No. PCT/US2018/059222 filed Nov. 5, 2018, PCT Application Publication No. WO2019143751, all of which are incorporated herein by reference in their entireties.

In one embodiment, the non-fullerene acceptor is (4,4,10,10-tetrakis(4-hexylphenyl)-5,11-(2-ethylhexyloxy)-4,10-dihydro-dithienyl[1,2-b:4,5b′]benzodi-thiophene-2,8-diyl)bis(2-(3-oxo-2,3-dihydroinden-1-ylidene)malononitrile) (herein referred to as “BT-IC”). BT-IC has planar structure with a small torsion angle <1° and consequently, a high electron mobility. In one embodiment, the non-fullerene acceptor is (4,4,10,10-tetrakis(4-hexylphenyl)-5,1 1-(2-ethylhexyloxy)-4,10-dihydro-dithienyl[1,2-b:4,5b]benzodi-thiophene-2,8-diyl) bis(2-(3-oxo-2,3-dihydroinden-5,6-dichloro-1-ylidene) malononitrile (BT-CIC). This structure provides a narrow absorption band confined to the near-infrared spectrum through the introduction of high electron affinity halogen atoms (e.g., chlorine atoms). In one embodiment, the non-fullerene acceptor is TT-FIC (4,4,10,10-tetrakis(4-hexylphenyl)-4,10-dihydrothieno [2″,3″:4′,5′]thieno[3′,2′:4,5] cyclopenta[1,2-b]thieno[2,3-d]thiophene-2,8-diyl)bis(2-(3-oxo-2,3-dihydroinden-5,6-difluoro-1-ylidene) malononitrile). Additional examples of suitable non-fullerene acceptors for use with the present invention may be found in PCT Application No. PCT/US2018/059222 filed Nov. 5, 2018, PCT Application Publication No. WO2019143751, all of which are incorporated herein by reference in their entireties.

Any donor molecule may be useful within the devices of the present invention, as would be understood by one of ordinary skill in the art. Non-limiting examples of useful donor molecules include phthalocyanines, such as copper phthalocyanine (CuPc), chloroaluminium phthalocyanine (ClAlPc), tin phthalocyanine (SnPc), zinc phthalocyanine (ZnPc), and other modified phthalocyanines, subphthalocyanines, such as boron subphthalocyanine (SubPc), naphthalocyanines, merocyanine dyes, boron-dipyrromethene (BODIPY) dyes, diindenoperylene (DIP), squaraine (SQ) dyes, tetraphenyldibenzoperiflanthene (DBP), 2-((7-(5-(dip-tolylamino)thiophen-2-yl)benzo[c][1,2,5]thiadiazol-4-yl)methylene)malononitrile (DTDCTB), 2 is (2-[(7-(4-[N,N-bis(4-methylphenyl) amino]phenyl)2,1,3-benzothia-diazol-4-yl) methylene]propane-dinitrile) (DTDCPB), 2-((7-(N-(isobutyl)-benzothieno[3,2-b]thieno[2,3-d]-pyrrol-2-yl)benzo[c][1,2,5] thiadiazol-4-yl) methylene)malononitrile (iBuBTDC), 2-{[2-(4-N,N-ditolylaminophenyl)-pyrimidin-5-yl]methylene}malononitrile (DTDCPP), poly[4,8-bis(5-(2-ethylhexyl)thiophen-2-yl)benzo[1,2-b;4, 5-b¹] dithiophene-2, 6-diyl-alt-(4-(2-ethylhexyl)-3-fluorothieno[3,4-b]thiophene-)-2-carboxylate-2-6-diyl)] (PCE-10), or a derivative thereofand derivatives thereof. Examples of squaraine donor materials include but are not limited to 2,4-bis [4-(N,N-dipropylamino)-2,6-dihydroxyphenyl] squaraine, 2,4-bis[4-(N,N-diisobutylamino)-2,6-dihydroxyphenyl] squaraine, 2,4-bis[4-(N,N-diphenylamino)-2,6-dihydroxyphenyl] squaraine (DPSQ). Additional non-limiting examples of useful donor molecules can be found in US 2018/0343966, filed Jan. 15, 2015, and PCT Application Publication No. WO2019143751, all of which are incorporated by reference herein in their entireties. In one embodiment, the donor molecule is DTDCPB. In another embodiment, the donor molecule is iBuBTDC. In one embodiment, the donor molecule is DTDCPP. In one embodiment, the donor is PCE-10.

In one aspect, the device of the present invention includes a layer comprised of a mixture of a donor molecule and at least one non-fullerene acceptor. In one embodiment, the layer includes a mixture of a donor molecule and one non-fullerene acceptor. In one embodiment, the layer includes a mixture of a donor molecule and two or more non-fullerene acceptors. In one embodiment, the two or more non-fullerene acceptors are different from each other. In one embodiment, the layer includes a donor molecule and a mixture of BT-CIC and TT-FIC. In one embodiment, the layer includes a mixture of PCE-10 and BT-CIC. In one embodiment, the layer includes a mixture of PCE-10 and TT-FIC. In one embodiment, the layer includes a mixture of PCE-10, BT-CIC and TT-FIC. In one embodiment, the layer consists of a mixture of PCE-10, BT-CIC, and TT-FIC.

In one embodiment, a device of the present invention comprises first and second subcells positioned between an anode and a cathode, with an optional recombination zone positioned between the first and second subcells. In one embodiment, the first subcell is positioned between the cathode and the recombination zone. In another embodiment, the second subcell is positioned between the recombination zone and the anode. In one embodiment, the first subcell is a ternary cell and the second subcell is a binary cell. In another embodiment, the first subcell is a binary cell and the second subcell is a ternary cell. In another embodiment, both the first and second subcells are ternary cells. In one embodiment a subcell can have a thickness of between 50 nm and 200 nm. In one embodiment, a subcell can have a thickness of between 50 nm and 100 nm. In one embodiment, a subcell can have a thickness of between 100 nm and 200 nm. In other embodiments, a subcell may have a thickness in a range of 60 nm to 90 nm, or 80 nm to 90 nm, or 120 nm to 180 nm, or 130 nm to 170 nm, or 150 nm to 170 nm. In one embodiment, a subcell has a thickness of about 84 nm or 85 nm. In another embodiment, a subcell has a thickness of about 160 nm or 170 nm.

In one embodiment, the ratio of the donor molecule to the non-fullerene acceptor is 1.5:1 to 1:1.5. In one embodiment, the ratio of the donor molecule to the non-fullerene acceptor is 1:1.5. In one embodiment, the layer includes one donor molecule and two non-fullerene acceptors, and the ratio of the donor molecule to the non-fullerene acceptors is 1:1.25:0.25 to 1:1.25:0.75. In one embodiment, the ratio of the donor molecule to the non-fullerene acceptors is about 1:1.25:0.25. In one embodiment, the ratio of the donor molecule to the non-fullerene acceptors is about 1:1.25:0.5. In one embodiment, the ratio of the donor molecule to the non-fullerene acceptors is about 1:1.25:0.75.

In one embodiment, the anode and/or the cathode is a conductive metal oxide, a metal layer, or a conducting polymer. Non-limiting examples of the conductive metal oxide include indium tin oxide, tin oxide, gallium indium tin oxide, zinc oxide, or zinc indium tin oxide. Non-limiting examples of the metal layer include Ag, Au, Pd, Pt, Ti, V, Zn, Sn, Al, Co, Ni, Cu, Cr, or combinations thereof. Non-limiting examples of the conductive polymer include polyanaline (PANT), or 3,4-polyethyl-enedioxythiophene:polystyrenesulfonate (PEDOT:PSS). In one embodiment, the conductive polymer is transparent.

The multi junction devices of the present disclosure may further comprise additional layers known in the art for photovoltaic devices, such as various buffer layers. For example, the devices may further comprise charge collection/transporting layers. Charge collection/transporting layers may be located, e.g., between a subcell and an electrode and/or between a subcell and a separating layer. It should be understood that charge collection/transporting layers will be chosen according to the desired carrier to be collected/transported. Examples of charge collecting/transporting layers include, but are not limited to, metal oxides. In certain embodiments, the metal oxides are chosen from MoO₃, V₂O₅, ZnO, and TiO₂.

As a further example, the devices may include exciton-blocking layers, including exciton-blocking charge-carrier filters, in addition to any exciton-blocking charge-carrier filters present in the separating layers. With regard to materials that may be used as an exciton blocking layer, non-limiting mention is made to those chosen from bathocuproine (BCP), bathophenanthroline (BPhen), 1,4,5,8-Naphthalene-tetracarboxylic-dianhydride (NTCDA), 3,4,9,10-perylenetetracarboxylicbis-benzimidazole (PTCBI), 1,3,5-tris(N-phenylbenzimidazol-2-yl)benzene (TPBi), tris(acetylacetonato) ruthenium(III) (Ru(acac)3), and aluminum(III)phenolate (Alq2 OPH), N,N′-diphenyl-N,N′-bis-alpha-naphthylbenzidine (NPD), aluminum tris(8-hydroxyquinoline) (Alq3), and carbazole biphenyl (CBP). In one embodiment, the material is BPhen.

These buffer layers may also serve as optical spacers to control the optical field distribution in the multi junction devices according to the design considerations disclosed herein.

In some embodiments, a device of the present invention comprises an anti-reflective coating (ARC). In one embodiment, the ARC is positioned in front of the anode and/or on an outer surface of the device. In another embodiment, the ARC is positioned between the anode and the cathode. In one embodiment, the ARC is positioned between the anode and a first subcell.

Layers and materials may be deposited using techniques known in the art. For example, the layers and materials described herein can be deposited or co-deposited from a solution, vapor, or a combination of both. In some embodiments, organic materials or organic layers are deposited or co-deposited using vacuum thermal evaporation, organic vapor phase deposition, or organic vapor-jet printing.

The PCE of the ternary cell is increased from 10.8±0.2% in a BT-CIC:PCE-10 cell to 12.6±0.3% in the BT-CIC:TT-FIC:PCE-10 ternary OPV. Furthermore, the short-circuit current density (J_{SC}) is increased from 22.3±0.4 mA cm′ to 25.5±0.3 mA cm′. Importantly, the absorption of the ternary cell is extended to 1000 nm with the energy loss (Eₗₒₛₛ=E_{g}−qV_{OC} where E_{g} is the smaller energy gap of either the donor or acceptor) decreased from 0.64 to 0.55 eV.

Although the PCE of ternary single junction solar cells exceeds 12%, their light absorption remains limited by the very thin active layer (˜100 nm) due to the low charge carrier mobility of the organic semiconductors. While energy conversion can be improved with a multi-junction architecture, the potential of ternary subcells in multi junction devices has not yet been substantially explored. In some embodiments, the disclosed device includes an anti-reflection-coated (ARC) tandem structure, combining both binary- and ternary-based OPVs, reaching PCE=15.4±0.3% under 1 sun, AM 1.5G simulated illumination (area=2 mm²).

### Experimental Examples

The invention is further described in detail by reference to the following experimental examples. These examples are provided for purposes of illustration only, and are not intended to be limiting unless otherwise specified. Thus, the invention should in no way be construed as being limited to the following examples, but rather, should be construed to encompass any and all variations which become evident as a result of the teaching provided herein.

Without further description, it is believed that one of ordinary skill in the art can, using the preceding description and the following illustrative examples, make and utilize the system and method of the present invention. The following working examples therefore, specifically point out the exemplary embodiments of the present invention, and are not to be construed as limiting in any way the remainder of the disclosure.

### Results

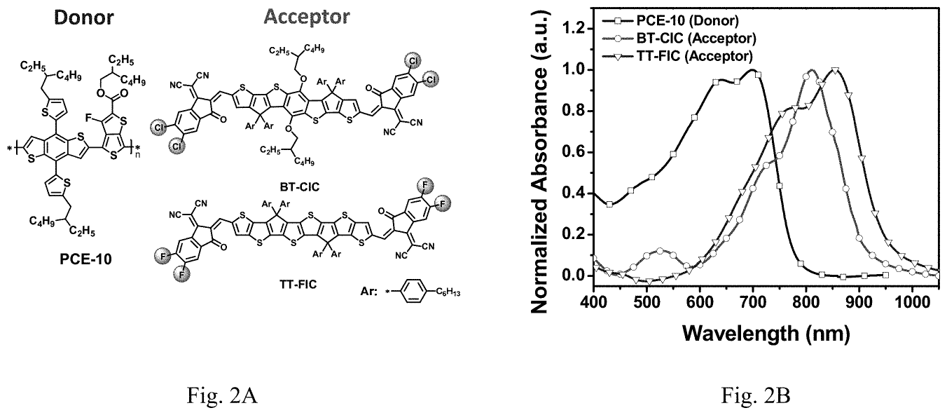

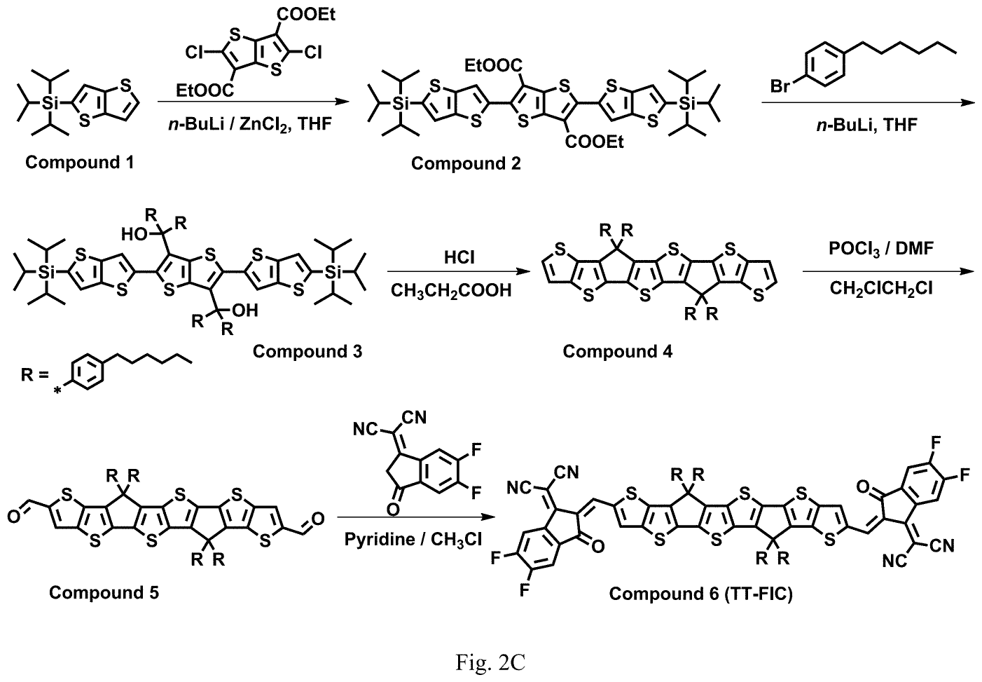

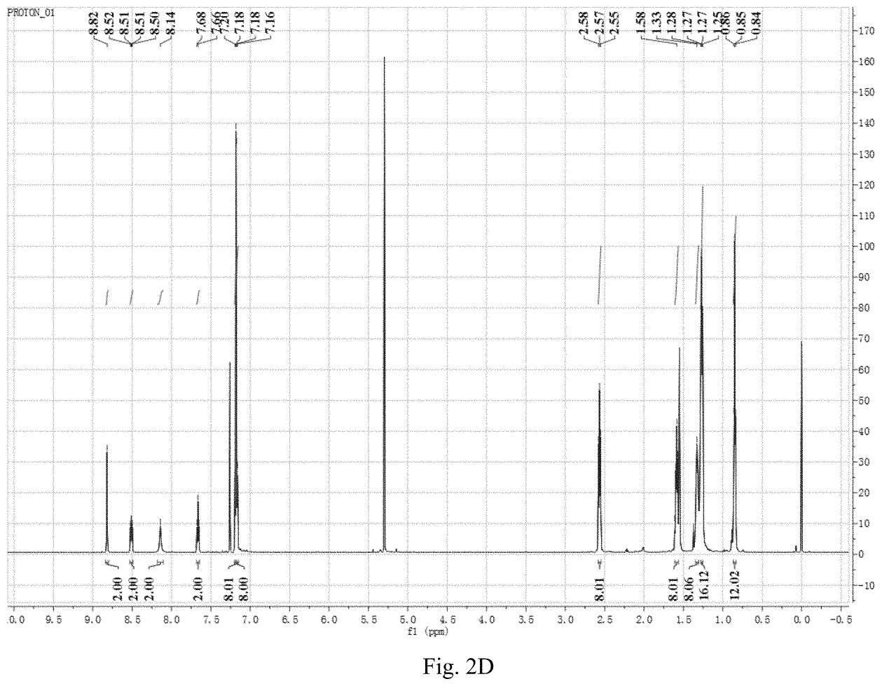

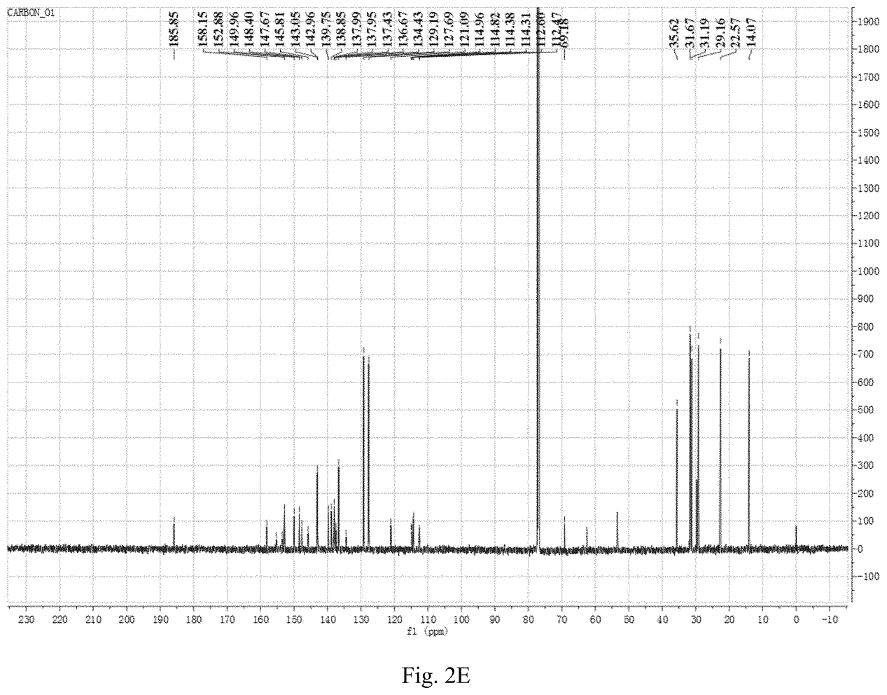

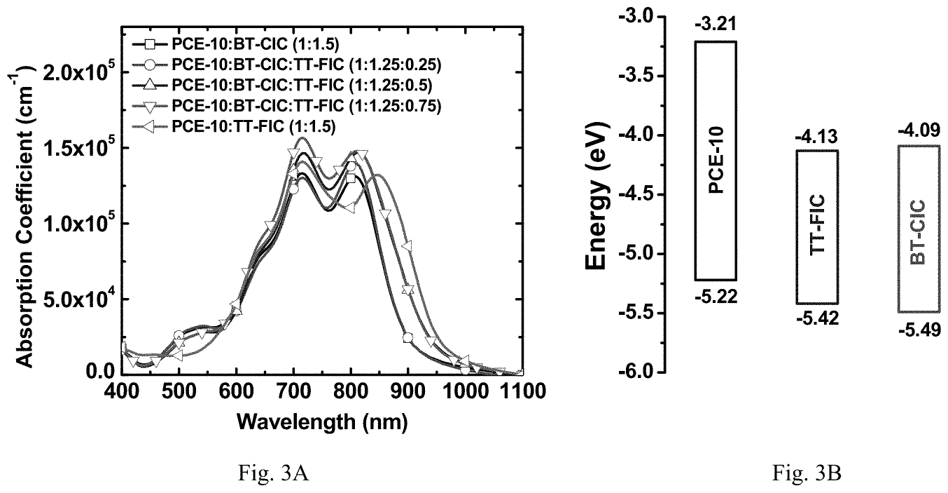

The chemical structures of the PCE-10, BT-CIC and TT-FIC are shown in FIG. 2A. The synthetic route for TT-FIC is shown in FIG. 2C. All materials are soluble in chloroform (CF), chlorobenzene (CB), and ortho-dichlorobenzene (o-DCB). Thin film absorption spectra of PCE-10, BT-CIC and TT-FIC are shown in FIG. 2B. In contrast to BT-CIC, the absorption spectrum of TT-FIC is red-shifted by 50 nm, resulting in absorption between λ=600 nm and 1000 nm and a small optical energy gap of 1.24 eV. The absorption of blended films with different weight ratios of TT-FIC are shown in FIG. 3A. With increasing TT-FIC content, the absorption between 600 and 1000 nm in the ternary blends gradually increases due to the change in NIR absorption by the addition of TT-FIC.

TT-FIC was synthesized using the following method, shown generally in FIG. 2C. 3-(dicyanomethylidene)-5,6-difluoro-indan-1-one (207 mg, 0.9 mmol) was added into the mixture of Compound 5 (171 mg, 0.15 mmol) in chloroform with pyridine (1 mL), the reaction was deoxygenated with nitrogen for 30 min and then reflux for 10 h. After cooling to room temperature, the reaction was poured into methanol and precipitate was filtered off. Then extracted with dichloromethane (DCM) and washed with water. The crude product was purified by silica gel column using a mixture of hexane/DCM as the eluent to give a purple solid (Compound 6, TT-FIC) (189 mg, 81%). ¹H NMR (600 MHz, CDCl₃, δ): 8.82 (s, 2H), 8.52 (t, J=12 Hz, 2H), 8.14 (s, 2H), 7.68 (t, J=12 Hz, 2H), 7.20 (d, J=12 Hz, 8H), 7.18 (d, J=12 Hz, 8H), 2.58 (t, J=12 Hz, 8H), 1.58 (m, 8H), 1.33-1.31 (m, 8H), 1.28-1.25 (m, 16H), 0.86 (t, J=6 Hz, 12H). ¹³C NMR (125 MHz, CDCl₃, 6) 185.85, 158.15, 155.27, 153.49, 152.88, 149.96, 148.40, 147.67, 145.81, 143.05, 142.96, 139.75, 138.85, 137.99, 137.95, 137.43, 136.67, 134.43, 129.19, 127.69, 121.09, 114.96, 114.82, 114.38, 114.31, 112.60, 112.47, 69.18, 35.62, 31.67, 31.19, 29.16, 22.57, 14.07. The ¹H NMR of TT-FIC in CDCl₃ is shown in FIG. 2D, and the ¹³C NMR of TT-FIC in CDCl₃ is shown in FIG. 2E.

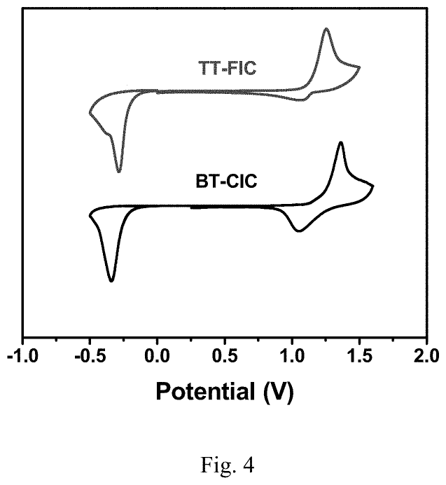

Cyclic voltammetry in FIG. 4 gives the HOMO (E_{HOMO}) and LUMO (E_{LUMO}) energies of −5.42 (±0.02) and −4.13 (±0.02) eV, respectively, for TT-FIC, and −5.49 (±0.02) and −4.09 (±0.02) eV for BT-CIC. TT-FIC shows a lower HOMO-LUMO energy gap (1.29 eV) than BT-IC (1.40 eV, see FIG. 3B), which is consistent with optical measurements. However, TT-FIC exhibits shallower HOMO and deeper LUMO energies compared with BT-CIC, which leads to a reduction of V_{OC} in TT-FIC based binary OPVs.

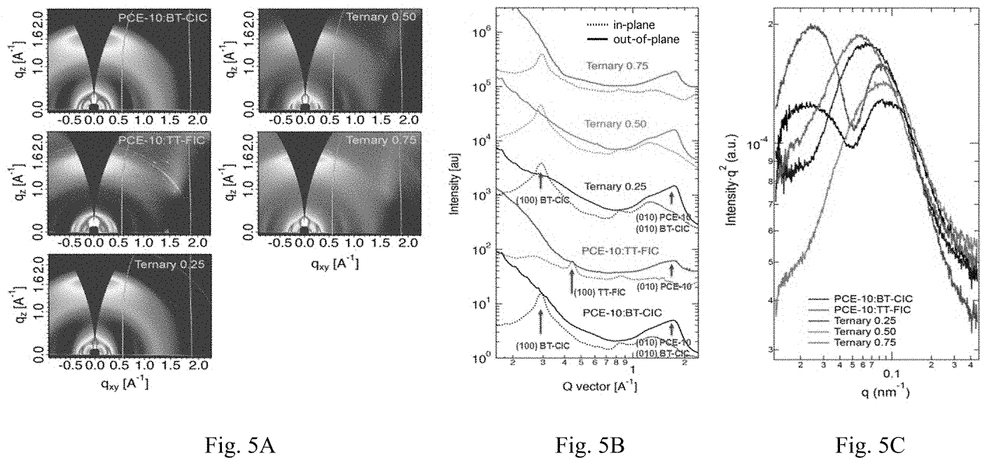

The morphologies of both the binary and ternary blends were characterized by grazing incidence x-ray diffraction. As shown in FIG. 5A, FIG. 5B, and FIG. 5C, the two binary blends show quite different solid-state ordering. The PCE-10:BT-CIC blends show more intense diffraction features with contributions from both PCE-10 and BT-CIC compared to PCE-10:TT-FIC. The crystal coherence length by peak fitting yielded a value of 13.0 nm. In contrast, PCE-10:TT-FIC blends exhibited a weak (100) diffraction peak (0.28 Å⁻¹) in the in-plane (IP) direction and the (010) diffraction peak (1.73 Å⁻¹) in out-of-plane (OP) direction.

This indicates that the crystallization of both PCE-10 and TT-FIC was decreased in the blends. In ternary blends, both PCE-10:BT-CIC:TT-FIC (1:1.25:0.25, w/w/w) and PCE-10:BT-CIC:TT-FIC (1:1.25:0.5, w/w/w) showed similar structural ordering compared to PCE-10:BT-CIC (1:1.5, w/w), but further increasing the content of TT-FIC to 0.75 caused only a small decrease in diffraction peak intensity. This suggests that PCE-10 and BT-CIC are guiding the morphology of the ternary mixture. The TT-FIC molecules located between PCE-10 and BT-CIC domains while leaving the size and structure of the PCE-10 and BT-CIC domains unchanged. Therefore, electron transport and collection occurred through the BT-CIC instead of TT-FIC. Thus, the TT-FIC functioned as a sensitizer. This is one possible reason that the addition of TT-FIC to PCE10: BT-CIC did not influence V_{OC} (see below).

Phase segregation within the blends was further studied by resonant soft x-ray diffraction, with results in FIG. 5C. Both of the PCE-10:BT-IC (1:1.5, w/w) and PCE-10:TT-FIC (1:1.5, w/w) blends showed a multi-length scaled morphology, with one peak at Q=0.085 (corresponding to a distance of 74 nm) and another at 0.025 Å⁻¹ (250 nm), suggesting structure at a dimension of hundreds of nanometers. In contrast, a single diffraction peak was observed in all three ternary blends, where PCE-10:BT-CIC:TT-FIC (1:1.25:0.5, w/w/w) exhibited the smallest scale for phase separation (74 nm) compared to the PCE-10:BT-CIC:TT-FIC (1:1.25:0.25, w/w/w, 94 nm) and PCE-10:BT-CIC:TT-FIC (1:1.25:0.75, w/w/w, 106 nm). The PCE-10:BT-CIC:TT-FIC blend film showed a high intensity peak at 0.067 Å⁻¹ (corresponding to a distance of 94 nm) in FIG. 5C, while the PCE-10:BT-CIC:TT-FIC blend showed a lower intensity peak at 0.085 A⁻¹ (corresponding to a distance of 74 nm). The higher intensity indicated greater domain purity, but the enlarged phase separation for PCE-10:BT-CIC:TT-FIC blend was inferior for charge extraction. Therefore, it is hard to predict the J_{SC} only from the morphology study.

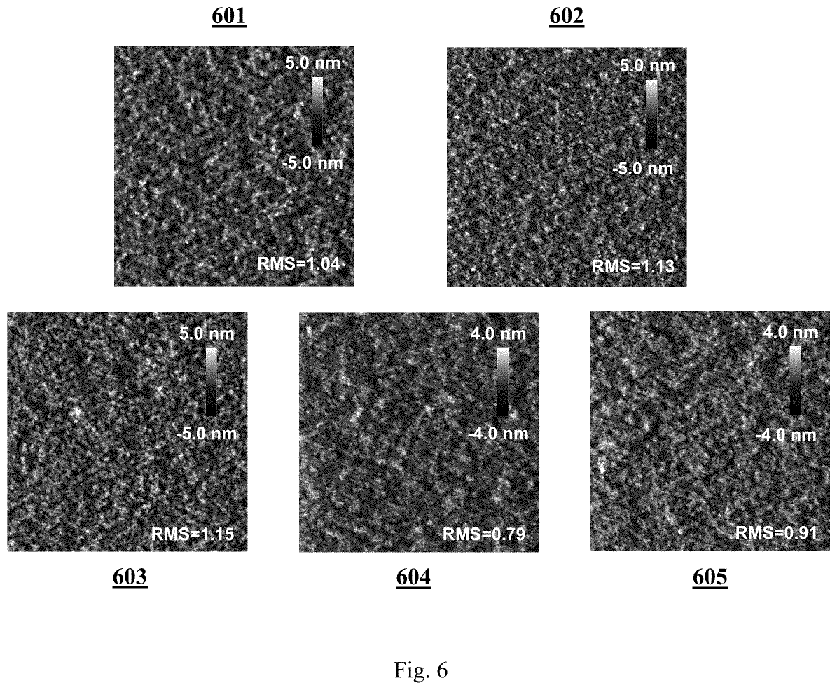

Atomic force microscopy (AFM) images of binary and ternary blends are shown in FIG. 6, PCE-10:BT-CIC:TT-FIC (1:1.25:0.5, w/w/w) blend with a root-mean-square roughness of 0.79 nm, compared with 1.15 nm for the PCE-10:BT-CIC:TT-FIC (1:1.25:0.25, w/w/w) and 0.91 nm for PCE-10:BT-CIC:TT-FIC (1:1.25:0.75, w/w/w) blends.

With reference to FIG. 6, image 601 shows PCE-10: BT-CIC (1:1.5, w/w), 602 shows PCE-10:TT-FIC (1:1.5, w/w), 603 shows PCE-10: BT-CIC:TT-FIC (1:1.25:0.25, w/w/w) 604 shows PCE-10: BT-CIC:TT-FIC (1:1.25:0.5, w/w/w), and 605 shows PCE-10: BT-CIC:TT-FIC (1:1.25:0.75, w/w/w) blend films cast from 9:1 chlorobenzene:chloroform solution.

Ternary OPVs were fabricated with the device structure: indium tin oxide (ITO)/poly(3,4-ethylenedioxythiophene)-poly(styrenesulfonate) (PEDOT:PSS) (50 nm)/PCE-10:BT-CIC:TT-FIC (1:1.25:x, 95 nm)/1,3,5-tri(m-pyridin-3-ylphenyl)benzene (TmPyPB) (5 nm)/Ag (100 nm). To systematically study the effects of the blend ratios, a binary cell was also prepared with the structure: ITO/PEDOT:PSS (50 nm)/PCE-10: TT-FIC (1:1.5, 100 nm)/ZnO (35 nm)/Ag (100 nm). The ZnO nanoparticles were used for the electron transporting layer to improve the contact between TmPyPB and PCE-10:TTFIC. Details of fabrication are found in the Methods section below.

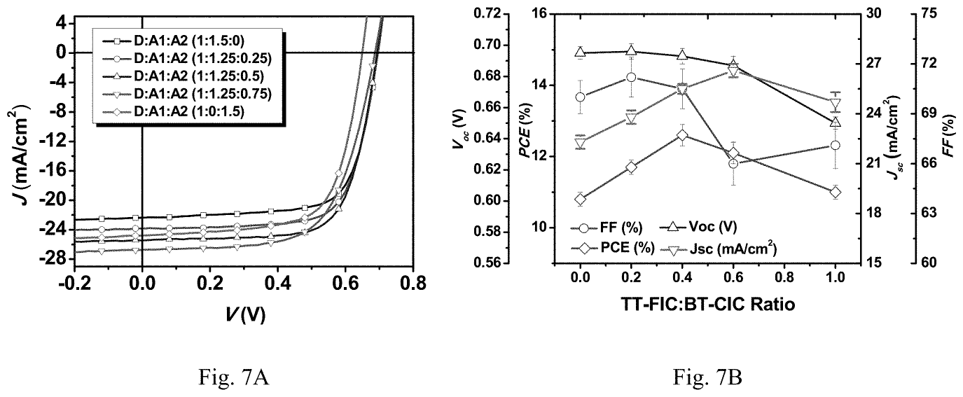

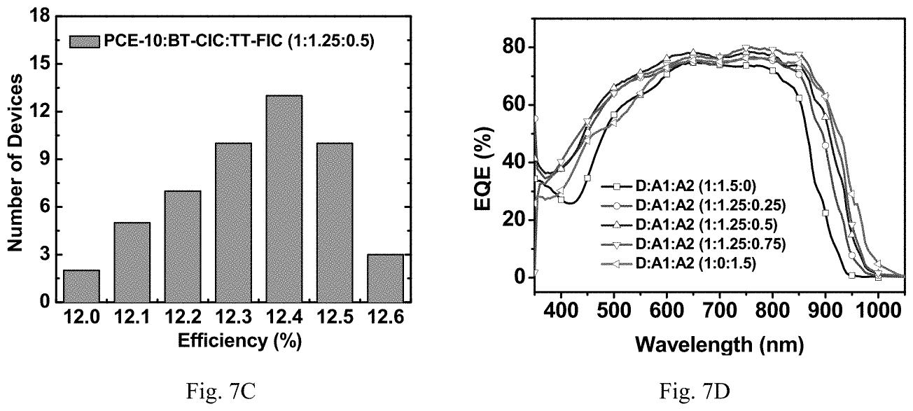

The current-density-voltage V) characteristics of PCE-10:BT-CIC:TT-FIC (1:x:y) blends are plotted in FIG. 7A, with a summary of device performance in Table 1 below. Compared to the BT-CIC, the TT-FIC-based binary device showed increased J_{SC} (24.7±0.6 mA cm⁻² vs. 22.3±0.4 mA cm⁻²), but decreased V_{OC} (0.650±0.004 V vs. 0.695±0.004 V) and fill factor (FF=0.67±0.01 vs. 0.70±0.01). The higher J_{SC} was due to absorption deeper into the NIR for TT-FIC. However, the increased LUMO energy of TT-FIC and decreased blend crystallization resulted in the lower V_{OC} and FF. In contrast to the PCE-10:BT-CIC binary cell, the incorporation of TT-FIC into the PCE-10:BT-CIC blend significantly increased J_{SC}, without changes to V_{OC} and FF. The trend in the performance of the ternary cells vs. acceptor blending ratio are shown in FIG. 7B. The optimized devices comprised 1:1.25:0.5 PCE-10:BT-CIC:TT-FIC, with PCE=12.6±0.3%, V_{OC}=0.693±0.005 V, J_{SC}=25.5±0.4 mA cm′, and FF=0.71±0.1. This was more than a 15% enhancement in PCE compared with the reference cell. This efficiency was among the highest value reported for ternary blend OPVs so far. FIG. 7C shows a PCE histogram for a population of 50 devices. The efficiencies fell in a narrow range between 12.0% and 12.6% with the mean value of 12.4%.

TABLE 1

| PCE-10:BT- | J_{sc} | V_{oc} | | PCE |
|---|---|---|---|---|
| CIC:TT-FIC | [mA/cm²] | [V] | FF | [%] |
| 1:1.5:0 | 22.3 ± 0.4 | 0.695 ± 0.004 | 0.70 ± 0.01 | 10.8 ± 0.2 |
| | (21.2) | | | |
| 1:1.25:0.25 | 23.8 ± 0.4 | 0.696 ± 0.005 | 0.71 ± 0.01 | 11.7 ± 0.2 |
| | (23.3) | | | |
| 1:1.25:0.5 | 25.5 ± 0.3 | 0.693 ± 0.005 | 0.71 ± 0.01 | 12.6 ± 0.3 |
| | (24.4) | | | |
| 1:1.25:0.75 | 26.6 ± 0.4 | 0.687 ± 0.006 | 0.66 ± 0.01 | 12.1 ± 0.3 |
| | (24.9) | | | |
| 1:0:1.5 | 24.7 ± 0.6 | 0.650 ± 0.004 | 0.67 ± 0.01 | 10.8 ± 0.2 |
| | (23.8) | | | |

With reference to Table 1 above, the operating characteristics of OPVs are shown under simulated conditions of AM 1.5G, 100 mW cm′, illumination. The J_{SC} values in parentheses were calculated from the integral of the EQE spectrum. The average PCE value was based on measurement of 50 devices.

The external quantum efficiencies (EQE) vs. wavelength are shown in FIG. 7D for several different ternary blend ratios. Increasing the TT-FIC content gradually increased EQE at long wavelengths. The integrated photocurrents from the EQE spectra were consistent with the J_{SC} values obtained using the solar simulator (see Table 1), confirming the high photocurrent generation efficiency in the ternary devices. Importantly, the EQE of the PCE-10:BT-CIC:TT-FIC (1:1.25:0.5, 95 nm) cell reached 75%, between λ=650 nm and 900 nm, while leaving a transparency window at A<600 nm. This made this device suitable for use as the back subcell (i.e. the cell adjacent to the reflective cathode) in a series-connected tandem OPV.

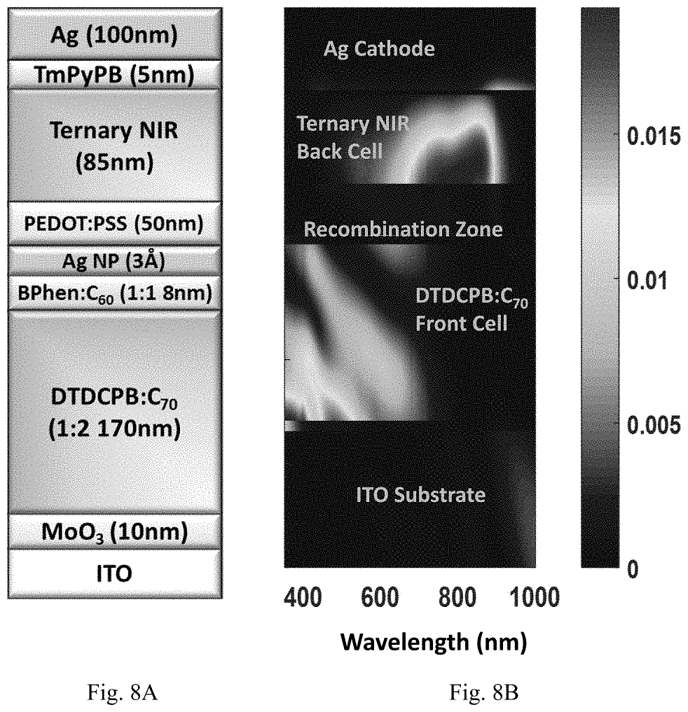

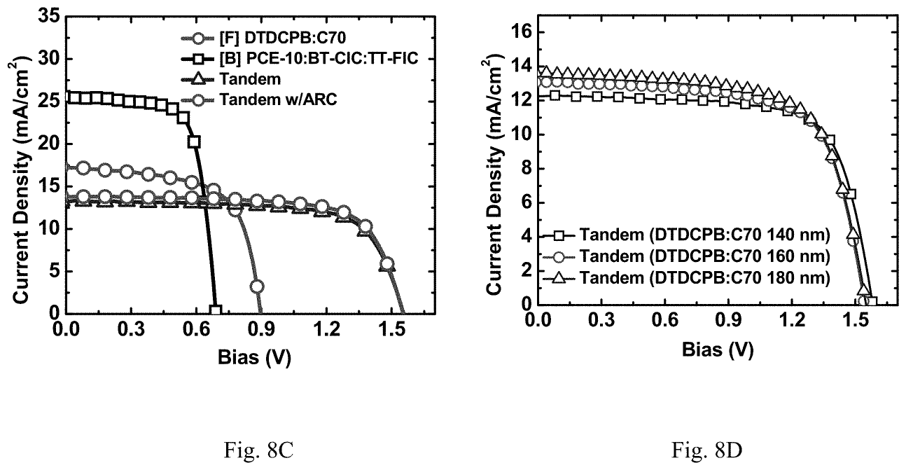

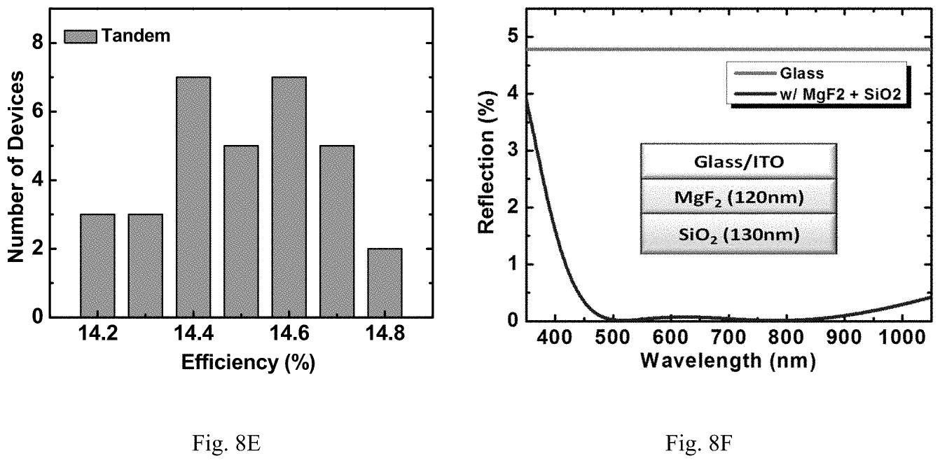

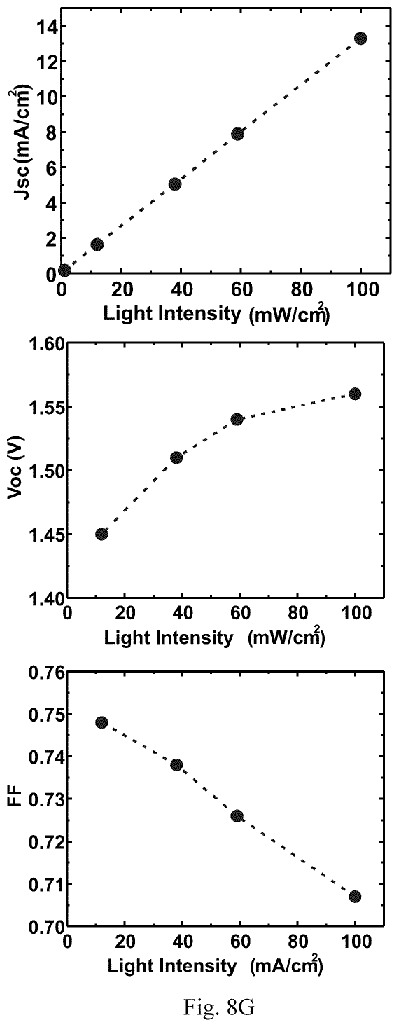

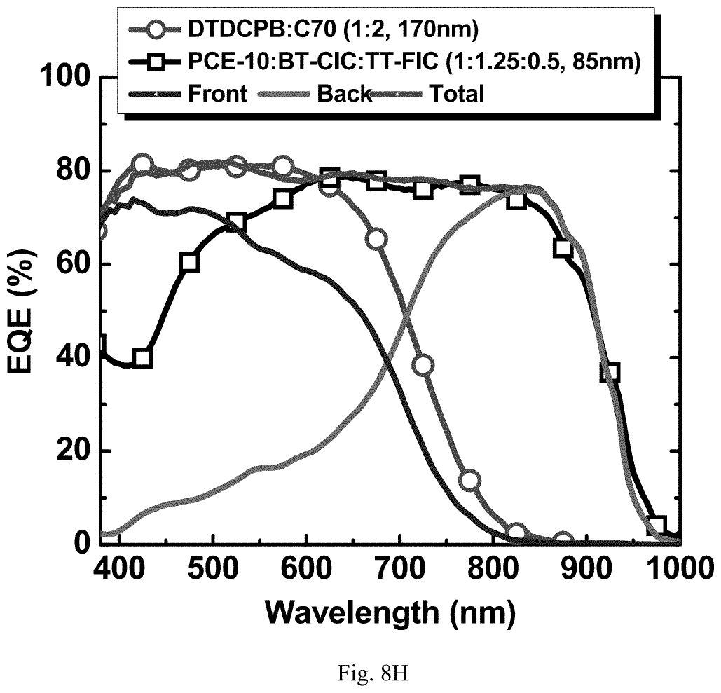

A DTDCPB:C₇₀ (1:2, w/w) blend was chosen as the active region of the front subcell of the tandem due to its response in the wavelength range from 350 nm to 600 nm. Therefore, DTDCPB:C₇₀ and PCE-10:BT-CIC:TT-FIC sub-cells were found to have complementary absorption spectra, as required in tandem solar cells. The tandem device structure is shown in FIG. 8A, where the DTDCPB:C₇₀ subcell grown by VTE, and the solution-processed PCE-10:BT-CIC:TT-FIC subcell was series connected with a charge recombination zone comprising bathophenanthroline (BPhen):C₆₀ (8 nm)/Ag NP/PEDOT:PSS (50 nm). The BPhen:C₆₀ served as an exciton blocking layer, the PEDOT:PSS functioned as both a hole transporting layer and a cap that protected the VTE-grown front subcell from penetration by the solution used in processing the back subcell. The 3 Å thick Ag nanoparticle layer promoted charge recombination. The simulated relative absorbed power distribution is displayed in FIG. 8B. The ternary back cell absorbed in the NIR from 700 nm to 950 nm, while the largest absorption occurred between λ=350 nm and 700 nm in the front cell. The charge recombination zone was nearly optically lossless. Note the non-overlapping spectra in the front (near the ITO) and back sub-cells leading to good current balance

FIG. 8C presents the J-V characteristics of the tandem cells, with details summarized in Table 2, below. As a result of insufficient light absorption by the DTDCPB:C₇₀ front subcell that lacked a reflecting metal cathode, thicker films were required to balance currents between the subcells compared to previously reported 80 nm thick single-junction structures. FIG. 8D shows the J-V characteristics of the tandem cells with various DTDCPB:C₇₀ thicknesses. The optimized tandem cell with 170 nm DTDCPB:C₇₀ together with the 85 nm PCE-10:BT-CIC:TT-FIC back subcell exhibited J_{SC}=13.3±0.2 mA/cm², V_{OC}=1.56±0.01 V, FF=0.71±0.01 and PCE=14.7±0.3% measured with mask to eliminate edge effects. In contrast to existing devices, (see Table 2) the J_{SC} for this tandem OPV had been increased due to the red-shifted absorption of the ternary subcell. The performance of the 9 mm² tandem cells are found in Table 2, showing ˜3% (relative) lower efficiency than the 2 mm² devices. Also of note is that the V_{OC} of the tandem equaled the sum of the V_{OC} of the single junction cells from which it is comprised, indicating the lossless charge recombination by the Ag NPs.

TABLE 2

| | J_{sc} | V_{oc} | | PCE |
|---|---|---|---|---|
| Device | (mA/cm²) | (V) | FF | (%) |
| [Back] | 24.8 ± 0.3 | 0.69 ± 0.01 | 0.70 ± 0.01 | 12.4 ± 0.2 |
| PCE-10:BT-CIC:TT-FIC | | | | |
| (1:1.25:0.5, 85 nm) | | | | |
| [Front] | 17.1 ± 0.3 | 0.90 ± 0.01 | 0.65 ± 0.01 | 10.0 ± 0.2 |
| DTDCPB:C₇₀ (1:2, 170 nm) | | | | |
| [Tandem] | 13.3 ± 0.2 (13.0) | 1.56 ± 0.01 | 0.71 ± 0.01 | 14.7 ± 0.3 |
| (w/ternary NIR subcells, 2 mm²) | | | | |
| [Tandem] | 12.7 ± 0.2 | 1.59 ± 0.01 | 0.71 ± 0.01 | 14.3 ± 0.3 |
| (w/binary NIR subcells, 2 mm²) | | | | |
| [Tandem] | 12.8 ± 0.3 (12.6) | 1.56 ± 0.01 | 0.71 ± 0.01 | 14.2 ± 0.3 |
| (w/ternary NIR subcells, 9 mm²) | | | | |
| [Tandem] | 13.8 ± 0.3 (13.5) | 1.56 ± 0.01 | 0.71 ± 0.01 | 15.4 ± 0.3 |
| (ternary cells + ARC, 2 mm²) | | | | |

With reference to Table 2, The J_{SC} values for the first, third, and fourth [Tandem] devices in the table were measured from devices using masks, the details of the measurements are found in the Methods section below. The J_{SC} values for the second [Tandem] device in the table were measured from devices without masks. The J_{SC} values in parentheses were calculated from the integral of the EQE spectrum using light bias with electrical bias corrected. The details of the measurement are found in the Methods section below.

FIG. 8E shows a PCE histogram of a population of 32 optimized tandem devices (2 mm² effective area, without antireflection coatings). The efficiencies fall in a narrow range between 14.2% and 14.8%. An antireflection coating (ARC) layer consisting of a 120 nm MgF₂ (index of refraction, n_{M}_{_{g}}_{F2}=1.38±0.01) and 130 nm SiO₂ deposited at glancing incidence to lower the refractive index to n_{SiO}_{₂}=1.12±0.03 was used to reduce optical losses and further increase the efficiency. The reflection ratio of the glass substrate with and without the ARC decreased by 4% between λ=400 nm and 1000 nm (see FIG. 8F, which is a graph of the measured reflection ratio between the glass substrates with an without the ARC). The ARC-coated tandem cell showed an increased J_{SC} from 13.3±0.2 mA/cm² to 13.8±0.3 mA/cm², thus leading to an increase in PCE=15.4±0.3%.

The J-V characteristics of tandem cells without ARC were also measured under incident light intensities varied from 12 to 100 mW cm′ using neutral density filters, with results shown in FIG. 8G. The J_{SC} is proportional to light intensity, indicating a lack of space charge build-up within the two subcells and in the charge recombination zone. The FF of the tandem devices increased to 75% under low light intensity, which was due to reduced charge recombination. The EQE spectra of the single junction DTDCPB:C₇₀ (1:2, 170 nm) and PCE-10:BT-CIC:TT-FIC (1:1.25:0.5, 85 nm) cells are plotted in FIG. 8H (circles and squares, respectively), as well as the individual sub-cells under illumination conditions experienced in the tandem cell. The symbols are for the discrete single junctions, while the magenta and blue lines are for the subcells in the stack obtained under light bias at wavelengths of 780 and 365 nm, and electrical bias of 0.45 and 0.75 V. The red line is the sum of the two measured EQEs obtained using light bias.

Measuring the EQE for a tandem cell was significantly more challenging compared to single junction solar cells. In the present experimental example, the EQE of tandem solar cells were obtained using modulated monochromatic (Thermo Oriel) probe light, which was mechanically chopped at a frequency of 200 Hz. Two LEDs (365 nm, Thorlabs, M365LP1 and 780 nm, Thorlabs, M780L3) were used for bias illumination with wavelengths tuned to excite the photoactive layers in the different subcells. Their intensities were varied with neutral density filters. The three light beams were combined at the tandem cell using lenses, mirrors, and a beam splitter. The sample was encapsulated in the N₂ filled glovebox by sealing a glass lid to the substrate using a bead of UV cured epoxy around its periphery. The packaged cells were maintained in the glovebox during the measurements. The measurements were executed with a lock-in-amplifier over a load of 50Ω. All data were recorded using Lab View. The electrical bias on the tandem cell was provided by the lock-in-amplifier.

The DTDCPB:C₇₀ front subcell was insensitive to light at wavelengths longer 780 nm, while PCE-10:BT-CIC:TT-FIC back subcell absorbed up to 1000 nm, as shown in FIG. 8H. As a result, bias illumination with a 780 nm light generated excess charges in the small energy gap back subcell, enabling measurement of the current-limiting wide band gap front subcell in the tandem architecture. On the other hand, the low absorption of the PCE-10:BT-CIC:TT-FIC back subcell in the range of 350 to 500 nm region enabled selective optical biasing of the small energy gap back subcell in the EQE measurement of the tandem cell with 365 nm bias illumination. For OPVs where charge collection is often field dependent, the reverse voltage bias that results from optically biased subcells created additional photocurrent and, hence, an overestimation of the EQE. Therefore, an additional forward electrical bias was applied to compensate the reverse bias created on the tandem cell. The electrical bias was determined by making use of J-V characteristics of single junction discrete cells under illumination conditions that are representative of the subcells in the tandem.

As shown in FIG. 8H, the subcells in the tandem architecture with the ARC absorb between λ=350 and 1000 nm, both exhibited a peak EQE˜75. The DTDCPB:C₇₀ (1:2, 170 nm) cell in the tandem exhibits a reduced EQE at 400<λ<700 nm compared to the single junction cell at the same thickness due to residual absorption by the PCE-10:BT-CIC:TT-FIC cell. The integrated J_{SC}=13.4 mA cm⁻² for the front subcell and J_{SC}=13.5 mA cm⁻² for the black subcell, led to balanced current generation in each subcell. Interestingly, the mathematical sum of the quantum efficiencies of the front and back subcells in the tandem featured a nearly wavelength-independent quantum efficiency ˜80% from λ=400 to 1000 nm.

### DISCUSSION

The development of small energy gap materials is essential to the progress of OPV technology, although there exist trade-offs between E_{g} and boss that ultimately limits their performance. Introducing a third NIR absorber into the active region appeared to balance this limitation, since ternary systems benefit by improving both the J_{SC} through NIR absorption while reducing boss, thus increasing V_{OC}. In this disclosure, the J_{SC} in the PCE-10:BT-CIC:TT-FIC ternary cell was significantly increased (from 22.3 mA cm⁻² to 25.5 mA cm⁻²), due to the increase in absorption between 600 and 1000 nm as TT-FIC is incorporated into the ternary blend. Additionally, the reduced phase separation in ternary blends increased the interfacial area between donors and acceptors, thus promoting exciton dissociation and giving rise to improved J_{SC}. Furthermore, the PCE-10:BT-CIC:TT-FIC based ternary cell showed a decreased boss compared to the PCE-10:BT-CIC binary cell (from 0.64 to 0.55 eV). This small boss was possibly due to the decreased HOMO energy offset with the NFAs and PCE-10 compared to BT-CIC.

Compared to the PCE-10:BT-CIC:TT-FIC (1:1.25:0.5, w/w/w) ternary cell, the TT-FIC-based binary device showed decreased J_{SC} (24.7±0.6 mA cm⁻² vs. 25.5±0.4 mA cm⁻²), V_{OC} (0.650±0.004 V vs. 0.693±0.005 V) and fill factor (FF=0.67±0.01 vs. 0.71±0.01). For the series connected multi junction devices, the voltage across the whole device was equal to the sum of the voltage across each sub-device according to Kirchhoff's law. In other words, the increased V_{OC} of each subcell in the ternary device resulted in improved V_{OC} of the tandem device. Moreover, the FFs of the tandem cells strongly relied on the FFs of each subcell. Therefore, the higher FF of the ternary subcell helps to further improve the performance of the tandem device.

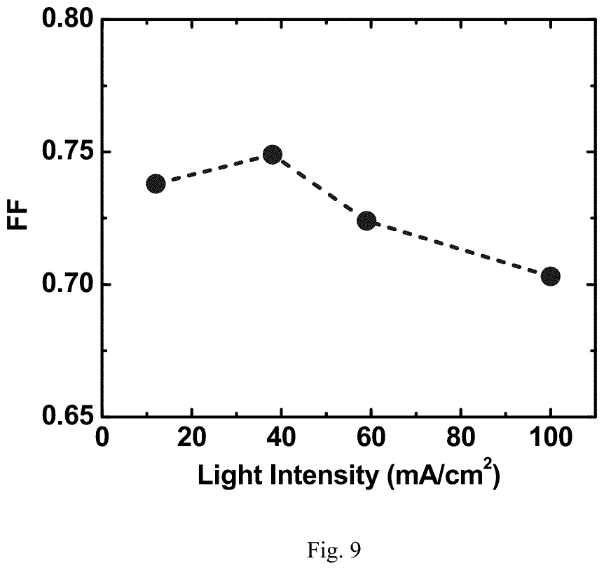

The PCE-10:BT-CIC:TT-FIC ternary device also achieved EQE=75% between the wavelengths of λ=650 nm and 900 nm, in addition to a transparency window between λ=350 nm and 650 nm. The tandem OPV that comprised the VTE-deposited fullerene binary subcell and the solution-processed ternary NIR subcell showed a higher PCE=15.4±0.3% with obvious increases in J_{SC} compared to the reference cell. The higher J_{SC} was attributed to the extended absorption of the ternary subcell. This suggests that the addition of ternary subcells with complementary absorption in tandem OPVs is a means for increasing PCE. Furthermore, a high FF=0.71 was achieved in the disclosed tandem device. This high FF was attributed to the lower light intensity in the ternary subcell, resulting in reduced current density and bimolecular recombination (see FIG. 9). FIG. 9 is a graph of the fill factor vs. light intensity for PCE-10:BT-CIC:TT-FIC (1:1.25:0.5, w/w/w) single junction cells.

### Durability Testing

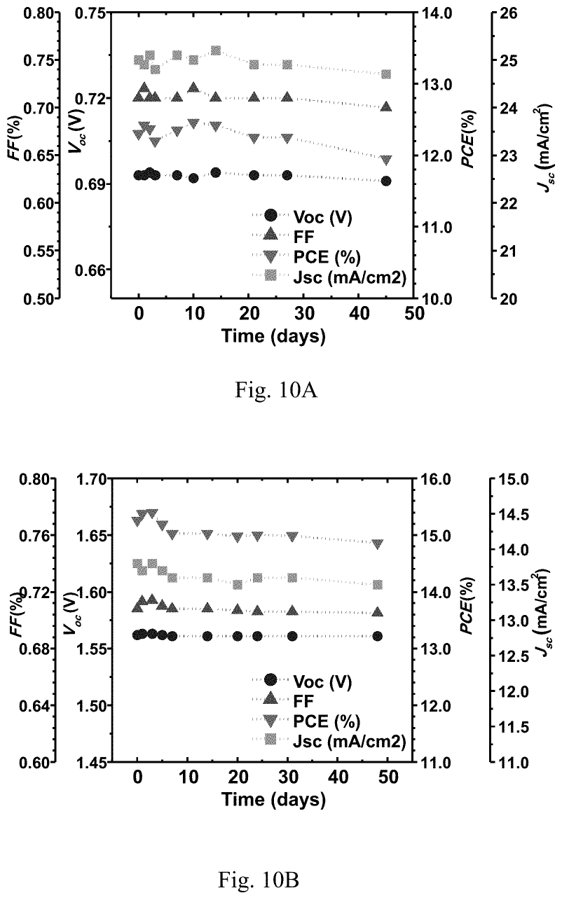

With reference now to FIG. 10A, a graph of measured ternary device parameters over time is shown. All depicted parameters are measurements of the same 2 mm² cell, and devices were kept in the dark between measurements. With reference to FIG. 10B, a graph of measured tandem device parameters over time is shown. All depicted parameters are measurements of the same 2 mm² cell, and devices were kept in the dark between measurements.

### Conclusion

In summary, the disclosed devices and methods demonstrate a highly efficient NIR-absorbing ternary solar cell with a polymer donor (PCE-10) and two NIR-absorbing NFAs (BT-CIC and TT-FIC). The second NFA component in the ternary blend extends absorption across a broader spectral range, achieves improved film morphology, and ultimately reduces energy losses. The optimized PCE-10:BT-CIC:TT-FIC based single junction cell exhibits PCE=12.6±0.3%. The tandem device structure incorporating a ternary NFA and a fullerene binary subcell shows PCE=15.4±0.3%.

### Methods—Materials

All devices were grown on patterned indium tin oxide (ITO) substrates with sheet resistance of 15 Ω/sq. The NIR absorbing-acceptor, BT-CIC and TT-FIC, were synthesized. Other materials were purchased from commercial suppliers: MoO₃ (Acros Organics); DTDCPB, BPhen and TmPyPB (Luminescence Technology Corp.); C₇₀ (SES Research); C₆₀ (MER Corp.); PEDOT:PSS (Clevios P VP AI. 4083, Heraeus); PCE-10 (1-Material); Ag (Alfa Aesar). DTDCPB, C₆₀ and C₇₀ were purified once by temperature-gradient sublimation prior to deposition.

### Methods—Single Junction Solar Cell Fabrication

Pre-patterned ITO on glass substrates were cleaned using a series of detergents and solvents followed by CO₂ snow cleaning and exposed to ultraviolet-ozone for 15 mins before growth. The PEDOT:PSS was filtered once with a 0.45 μm Nylon syringe filter prior to use, and then spin-coated onto the substrate at 5000 rpm for 60 s. The active layer, PCE-10:BT-CIC:TT-FIC (1:x:y w/w/w), was dissolved in chlorobenzene:chloroform (CB:CF, 9:1 by vol.) with a concentration of 20 mg/ml. The solution was stirred overnight on a hot plate at 65° C., and then spin-coated at 2000 rpm for 90 s to achieve a thickness of ˜95 nm. The samples were then transferred back to the vacuum chamber for deposition of TmPyPB and the Ag cathode. For the PCE-10:TT-FIC based device, ZnO nanoparticles were used for an electron transporting layer. The device areas of 2.0 and 9.0 mm² were defined by the overlap between the patterned ITO and the Ag cathode deposited through an ultrathin shadow mask (50 μm).

### Methods—Tandem Solar Cell Fabrication

Pre-patterned ITO on glass substrates were cleaned using a series of detergents and solvents followed by CO₂ snow cleaning and exposed to ultraviolet-ozone for 15 mins before growth. The vacuum-deposited layers for the front cell were grown at ˜1 Å/s in a high vacuum chamber with a base pressure of 2×10⁻⁷ torr. During co-deposition of the VTE-grown DTDCPB:C₇₀ (1:2, w/w) layer, the deposition rate of each material was monitored by individual crystal sensors to achieve the desired volume ratios. After growing the active layer, a recombination zone consists of three layers: a 3 Å thick Ag NP layer deposited on the BPhen:C₆₀ mixed (1:1, w/w), followed by spin-coating the PEDOT:PSS was built up. The vacuum chamber was connected to glove boxes filled with ultrapure N₂ (O₂, H₂O<0.1 ppm) where the solution processed layers were subsequently deposited. The back NIR cells were made according to the single junction procedure. The ARC was grown onto the glass substrate after the devices were complete. MgF₂ was deposited by VTE while the SiO₂ was grown by electron beam deposition with the substrate at an angle of 85° to the beam direction to achieve a low refractive index of 1.1.

### Methods—Solar Cell Characterization

The current density-voltage (J-V) characteristics and spectrally resolved external quantum efficiencies (EQE) were measured in a glove box filled with ultrapure N₂ (<0.1 ppm). Light from a Xe lamp filtered to achieve a simulated AM 1.5G spectrum (ASTM G173-03) was used as the source for J-V measurements. The lamp intensity controlled by neutral density filters was calibrated using a standard Si reference cell (with a KG-2 filter) traceable to certification by National Renewable Energy Laboratory (NREL). The illumination intensity was adjusted using neutral density filters. Each cell was measured under six different light intensities from 0.001 sun to 1 sun (100 mW/cm²). Errors quoted account for variations from three or more cells measured, as well as an additional systematic error of 5% for J_{SC} and PCE. The devices were masked with a metal aperture to define the active area of 0.012±0.001 and 0.063±0.001 cm′ and measured in a light-tight sample holder to minimize edge effects. This ensured that both the reference and test cells were co-located under the solar simulator during measurement. The EQE measurements were performed with devices underfilled by a 200 Hz-chopped monochromated and focused beam from a Xe lamp. The current outputs from the devices as well as from a reference NIST-traceable Si detector were recorded using a lock-in amplifier. The EQE of the individual sub-cells in the tandem devices were measured by using both an optical and electrical bias. There is a ˜2% difference between the integrated J_{SC} from light bias EQE measurements to that using the solar simulator with a mask.

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention. The appended claims are intended to be construed to include all such embodiments and equivalent variations.

1. A photovoltaic cell comprising:
an anode;
a cathode;
a first subcell positioned between the anode and the cathode, the first subcell comprising a first donor material and a first acceptor material; and
a second subcell positioned between the first subcell and the cathode, the second subcell comprising a second donor material and a second acceptor material;
wherein the first or second subcell comprises more than one donor or acceptor material.

2-4. (canceled)

5. The photovoltaic cell of claim 1, wherein the first subcell further comprises a third acceptor material and the second subcell further comprises a third donor material.

6. The photovoltaic cell of claim 2, wherein the second and third acceptor materials are NIR non-fullerene acceptor materials.

7. The photovoltaic cell of claim 4, wherein the second, third, and fourth acceptor materials are NIR non-fullerene acceptor materials.

8-9. (canceled)

10. The photovoltaic cell of claim 1, further comprising a recombination zone comprising at least one layer, positioned between the first subcell and the second subcell.

11. The photovoltaic cell of claim 10, wherein the recombination zone comprises a material selected from the group consisting of PEDOT:PSS, Ag, BPhen, and Fullerene.

12. (canceled)

13. The photovoltaic cell of claim 1, further comprising an anti-reflective coating.

14. The photovoltaic cell of claim 13, wherein the anti-reflective coating comprises a material selected from the group consisting of MgF₂ and SiO₂.

15-18. (canceled)

19. The photovoltaic cell of claim 1, further comprising an electron transport layer positioned between the second subcell and the cathode.

20. The photovoltaic cell of claim 19, wherein the electron transport layer comprises TmPyPB.

21. A method of fabricating a photovoltaic cell, comprising:
positioning a substrate in a first chamber;
establishing a vacuum in the first chamber;
depositing a first subcell comprising at least one material over the substrate;
depositing a recombination zone over the first subcell;
moving the substrate, first subcell, and recombination zone to a second chamber comprising ultrapure N₂ gas; and
depositing a second subcell over the recombination zone in the second chamber.

22. (canceled)

23. The method of claim 21, further comprising depositing an anti-reflective coating on the substrate.

24. The method of claim 23, wherein the anti-reflective coating is deposited by VTE or electron beam deposition.

25. The method of claim 21, further comprising patterning an anode on the substrate prior to depositing the first subcell.

26. (canceled)

27. The method of claim 21, further comprising moving the photovoltaic cell back to the first chamber after depositing the second subcell and establishing a vacuum in the first chamber.

28. (canceled)

29. The method of claim 27, further comprising depositing an electron transport layer over the second subcell.

30. The method of claim 21, further comprising the steps of:
forming a second subcell material, comprising the steps of:
dissolving at least one material in chlorobenzene:chloroform to form a mixture;
stirring the mixture; and
heating the mixture to form the second subcell material; and
spin-coating the second subcell material over the recombination zone to form the second subcell.

31. The method of claim 30, wherein the at least one material is selected from the group consisting of PCE-10, BT-CIC, TT-FIC, and a compound of formula (I)-(III) 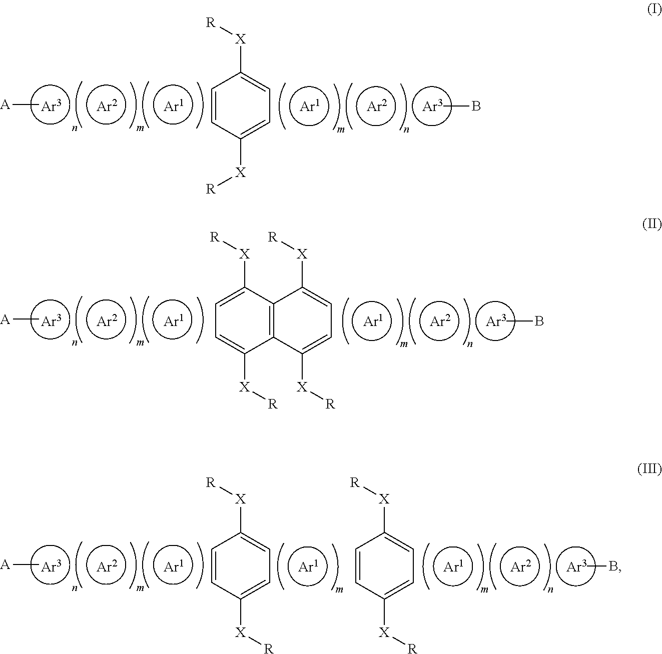
wherein Ar¹, Ar² and Ar³ each individually represent aromatic groups;
each m is independently an integer from 0 to 10;
each n is independently an integer from 0 to 10;
each X is independently selected from the group consisting of oxygen, carbon, hydrogen, sulfur, selenium and nitrogen;
each R is individually linear or branched saturated or unsaturated non-aromatic hydrocarbon in the C₁-C₂₀ range; and
A and B are each independently selected from the group consisting of: 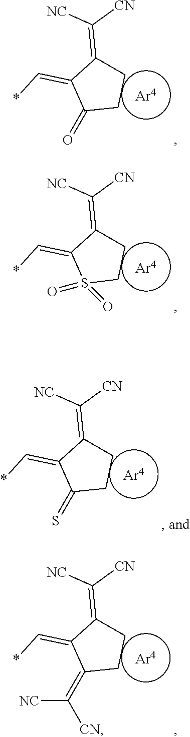
wherein Ar⁴ is an aromatic group which is fused to the adjacent ring.

32. The method of claim 30, wherein the at least one material consists of PCE-10, BT-CIC, TT-FIC, and a compound of formula (I)-(III) 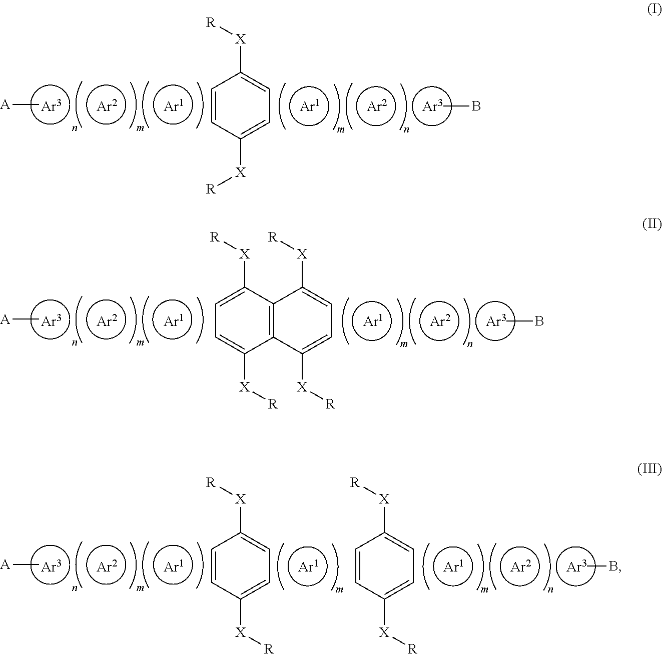
wherein Ar¹, Ar² and A³ each individually represent aromatic groups;
each m is independently an integer from 0 to 10;
each n is independently an integer from 0 to 10;
each X is independently selected from the group consisting of oxygen, carbon, hydrogen, sulfur, selenium and nitrogen;
each R is individually linear or branched saturated or unsaturated non-aromatic hydrocarbon in the C₁-C₂₀ range; and
A and B are each independently selected from the group consisting of: 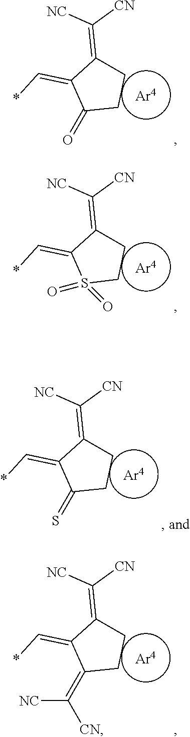
wherein Ar⁴ is an aromatic group which is fused to the adjacent ring.

33. A compound of one of formula (I)-(III) 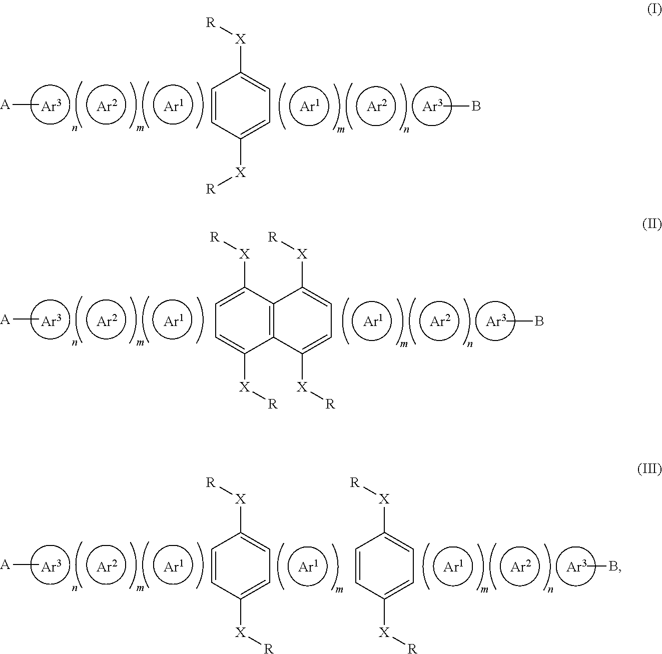
wherein Ar¹, Ar² and Ar³ each individually represent aromatic groups;
each m is independently an integer from 0 to 10;
each n is independently an integer from 0 to 10;
each X is independently selected from the group consisting of oxygen, carbon, hydrogen, sulfur, selenium and nitrogen;
each R is individually linear or branched saturated or unsaturated non-aromatic hydrocarbon in the C₁-C₂₀ range; and
A and B are each independently selected from the group consisting of: 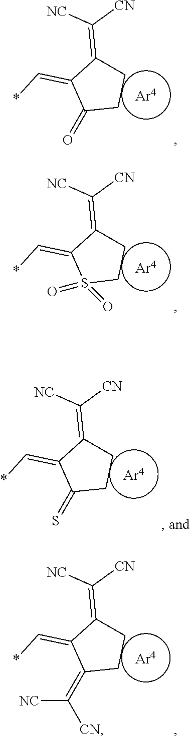
wherein Ar⁴ is an aromatic group which is fused to the adjacent ring.
